(19) United States
(12) Patent Application Publication
(10) Pub. No.: US 2026/0074718 A1
(43) Pub. Date: Mar. 12, 2026

(54) RADIO FREQUENCY CIRCUIT

(71) Applicant: Murata Manufacturing Co., Ltd., Nagaokakyo-shi (JP)

(72) Inventors: Hirotsugu MORI, Nagaokakyo-shi (JP); Atsushi HORITA, Nagaokakyo-shi (JP)

(73) Assignee: Murata Manufacturing Co., Ltd., Nagaokakyo-shi (JP)

(21) Appl. No.: 19/387,950

(22) Filed: Nov. 13, 2025

Related U.S. Application Data
(63) Continuation of application No. PCT/JP2024/012435, filed on Mar. 27, 2024.

(30) Foreign Application Priority Data
May 17, 2023 (JP) 2023-081888

(51) Int. Cl. H04B 1/00; H03H 9/54; H03H 9/72; H04B 1/50

(52) U.S. Cl. CPC H04B 1/006; H03H 9/54; H03H 9/72; H04B 1/50

(57) ABSTRACT

A radio frequency circuit includes: a first filter having a passband including uplink bands of first and second bands (UL1,UL2); a second filter having a passband including a downlink band of the first band (DL1); and a downlink filter arrangement that filters a downlink band of the second band (DL2) and a downlink band of a third band (DL3). All filter paths are ultimately communicatively coupled to an antenna terminal, either directly or via a switch. The combination of the first and second bands is a band combination for simultaneous communication. The frequency ordering is DL2>DL3>UL2>UL1>DL1. The first filter has a steeper attenuation slope on a higher frequency side than on a lower frequency side of the passband.

### CROSS-REFERENCE TO RELATED APPLICATIONS

This is a continuation application of PCT International Application No. PCT/JP2024/012435 filed on Mar. 27, 2024, designating the United States of America, which is based on and claims priority to Japanese Patent Application No. 2023-081888 filed on May 17, 2023. The entire disclosures of the above-identified applications, including the specifications, drawings, and claims are incorporated herein by reference in their entirety.

### TECHNICAL FIELD

The present disclosure relates to a radio frequency circuit.

### BACKGROUND

Mobile communication devices such as mobile phones increasingly operate on many frequency bands (“multi-band”). This requires their front-end circuits to become larger. U.S. Patent Application Publication No. 2015/0133067 discloses a radio frequency circuit that includes a plurality of filters for a plurality of frequency bands.

### SUMMARY

### Technical Problems

However, as conventional radio frequency circuits incorporate multi-band functionality, they inevitably require an increased number of filters.

In view of this, the present disclosure provides a radio frequency circuit that can inhibit an increase in the number of filters required for multi-band functionality.

### Solutions

A radio frequency circuit according to one aspect of the present disclosure includes: a first filter having a passband that includes an uplink band of a first band and an uplink band of a second band; a second filter having a passband that includes a downlink band of the first band; a third filter having a passband that includes a downlink band of the second band; a fourth filter having a passband that includes a downlink band of a third band; and a switch that includes a first terminal connected to a first antenna connection terminal, a second terminal connected to the first filter, the second filter, and the third filter, and a third terminal connected to the fourth filter. A combination of the first band and the second band is a band combination for simultaneous communication. The uplink band of the first band is higher than the downlink band of the first band. The uplink band of the second band is higher than the uplink band of the first band. The downlink band of the second band is higher than the uplink band of the second band. The downlink band of the third band is higher than the uplink band of the second band and lower than the downlink band of the second band. The first filter has a steeper attenuation slope on a higher frequency side of the passband than on a lower frequency side of the passband.

A radio frequency circuit according to one aspect of the present disclosure includes: a first filter adjustable to a first passband that includes an uplink band of a first band and an uplink band of a second band, and a second passband that includes the uplink band of the first band and is narrower than the first passband; a second filter having a passband that includes a downlink band of the first band; a third filter having a passband that includes a downlink band of the second band; a fourth filter having a passband that includes a downlink band of a third band; and a switch that includes a first terminal connected to an antenna connection terminal, a second terminal connected to the first filter and the second filter, a third terminal connected to the third filter, and a fourth terminal connected to the fourth filter. A combination of the first band and the second band is a band combination for simultaneous communication. The uplink band of the first band is higher than the downlink band of the first band. The uplink band of the second band is higher than the uplink band of the first band. The downlink band of the second band is higher than the uplink band of the second band. The downlink band of the third band is higher than the uplink band of the second band and lower than the downlink band of the second band. The first filter has a steeper attenuation slope on a higher frequency side of the first passband than on a lower frequency side of the first passband.

A radio frequency circuit according to one aspect of the present disclosure includes: a first filter adjustable to a first passband that includes an uplink band of a first band and an uplink band of a second band, and a second passband that includes the uplink band of the first band and is narrower than the first passband; a second filter having a passband that includes a downlink band of the first band; a third filter adjustable to a third passband that includes a downlink band of the second band and a downlink band of a third band, and a fourth passband that includes the downlink band of the second band and is narrower than the third passband. A combination of the first band and the second band is a band combination for simultaneous communication. The uplink band of the first band is higher than the downlink band of the first band. The uplink band of the second band is higher than the uplink band of the first band. The downlink band of the second band is higher than the uplink band of the second band. The downlink band of the third band is higher than the uplink band of the second band and lower than the downlink band of the second band. The first filter has a steeper attenuation slope on a higher frequency side of the first passband than on a lower frequency side of the first passband.

### Advantageous Effects

A radio frequency circuit and a communication device according to one aspect of the present disclosure can inhibit an increase in the number of filters required for multi-band functionality.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates a circuit configuration of a communication device according to Embodiment 1.

FIG. 2 illustrates frequency bands related to Embodiment 1.

FIG. 3 illustrates a graph showing frequency characteristics of a filter according to Embodiment 1.

FIG. 4 illustrates a circuit configuration of a filter according to Embodiment 1.

FIG. 5A illustrates a cross-sectional view of a filter according to Embodiment 1.

FIG. 5B illustrates a cross-sectional view of a variation of a filter according to Embodiment 1.

FIG. 6 illustrates a first communication mode of a communication device according to Embodiment 1.

FIG. 7 illustrates a second communication mode of a communication device according to Embodiment 1.

FIG. 8 illustrates a circuit configuration of a communication device according to a variation of Embodiment 1.

FIG. 9 illustrates a third communication mode of a communication device according to a variation of Embodiment 1.

FIG. 10 illustrates a circuit configuration of a communication device according to Embodiment 2.

FIG. 11 illustrates a graph showing frequency characteristics of a filter according to Embodiment 2.

FIG. 12 illustrates a graph showing frequency characteristics of a filter according to Embodiment 2.

FIG. 13 illustrates a first communication mode of a communication device according to Embodiment 2.

FIG. 14 illustrates a second communication mode of a communication device according to Embodiment 2.

FIG. 15 illustrates a circuit configuration of a communication device according to Embodiment 3.

FIG. 16 illustrates a graph showing frequency characteristics of a filter according to Embodiment 3.

FIG. 17 illustrates a graph showing frequency characteristics of a filter according to Embodiment 3.

FIG. 18 illustrates a first communication mode of a communication device according to Embodiment 3.

FIG. 19 illustrates a second communication mode of a communication device according to Embodiment 3.

### DESCRIPTION OF EMBODIMENTS

The following describes in detail embodiments of the present disclosure, with reference to the drawings. Note that the embodiments described below each show a general or specific example. The numerical values, shapes, materials, elements, and the arrangement and connection of the elements, for instance, described in the following embodiments are examples, and thus are not intended to limit the present disclosure.

Note that the drawings are schematic diagrams to which emphasis, omission, and ratio adjustment are appropriately added in order to illustrate the salient features of the present disclosure, and thus are not necessarily accurate or complete illustrations with respect to a commercial product. For example, the drawings may show shapes, positional relations, and ratios that are different from actual shapes, actual positional relations, and actual ratios. Throughout the drawings, the same numeral is given to substantially the same element, and redundant description may be omitted or simplified.

In the circuit configurations, being connected includes not only being directly connected by a connection terminal and/or a line conductor, but also being electrically connected via another circuit element. C being connected between A and B means that one end of C is connected to A and the other end of C is connected to B, and means that C is connected in series onto a path that connects A and B. A “terminal” means a point at which a conductor in an element ends. Note that under a condition that an impedance of a conductor between elements is sufficiently low, a terminal may be interpreted not only as a single fixed point, but as any point on the conductor between the elements or as the entire conductor.

“Band X being higher than Band Y” means that a center frequency of Band X is higher than a center frequency of Band Y. Conversely, “Band X being lower than Band Y” means that a center frequency of Band X is lower than a center frequency of Band Y.

Furthermore, a “passband of a filter” is a portion of a frequency spectrum of a signal transferred by a filter and is defined as a frequency band in which an output power is not attenuated by 3 dB or more from a maximum output power. Thus, a high-frequency edge and a low-frequency edge of a passband of a bandpass filter are identified as a higher frequency and a lower frequency at two points at which an output power is attenuated by 3 dB from a maximum output power.

The “attenuation slope on the lower frequency side of a filter passband” is defined by the amount of gain reduction from the low-frequency edge of the filter passband to a frequency 1 MHz lower than the low-frequency edge. Thus, the “attenuation slope on the lower frequency side of a filter passband” is represented by the difference between the gain at the low-frequency edge of the filter passband and the gain at a frequency 1 MHz lower than the low-frequency edge. Conversely, the “attenuation slope on the higher frequency side of a filter passband” is defined by the amount of gain reduction from the high-frequency edge of the filter passband to a frequency 1 MHz higher than the high-frequency edge. Thus, the “attenuation slope on the higher frequency side of a filter passband” is represented by the difference between the gain at the high-frequency edge of the filter passband and the gain at a frequency 1 MHz higher than the high-frequency edge. Such attenuation slope is identified by removing the filter from the mounting substrate, mounting the filter alone on a dedicated test elementary group (TEG) substrate, and measuring its pass characteristics. Note that in a case in which the pass characteristics of the filter change when the filter is removed from the mounting substrate, the attenuation slope can be identified by connecting probes to the input terminal and output terminal of the filter on the mounting substrate and measuring the pass characteristics of the filter.

A “downlink band” is a downlink operating band, and means a portion of a communication band that is designated for downlink communication. Thus, a “downlink band” means a band that is utilized to transfer radio frequency signals from a base station (BS) to a user equipment (UE) in frequency division duplex (FDD) or supplementary downlink (SDL).

In contrast, an “uplink band” is an uplink operating band, and means a portion of a communication band that is designated for uplink communication. Thus, an “uplink band” means a band that is utilized to transfer radio frequency signals from a UE to a BS in FDD or supplementary uplink (SUL).

A “band combination for simultaneous communication” means a plurality of bands predefined as a combination that can be used for simultaneous transmission, simultaneous reception, or simultaneous transmission and reception. The definition of “band combination for simultaneous communication” is made by standardizing bodies (such as the 3rd Generation Partnership Project (3GPP (registered trademark)) and the Institute of Electrical and Electronics Engineers (IEEE), for example). A “band combination for simultaneous communication” is defined as a band combination for carrier aggregation (CA), E-UTRAN New Radio-Dual Connectivity (EN-DC), New Radio-Dual Connectivity (NR-DC), or New Radio E-UTRAN-Dual Connectivity (NE-DC), for example.

### Embodiment 1

First, Embodiment 1 will be described. Communication device 5 according to the present embodiment can be used to provide wireless connectivity. For example, communication device 5 can be implemented in user equipment (UE) in a cellular network (also referred to as a mobile network), such as a mobile phone, smartphone, tablet computer, or wearable device. In another example, by implementing communication device 5, wireless connectivity can be provided to Internet of Things (IoT) sensor/devices, medical/health care devices, vehicles, unmanned aerial vehicles (UAV) (also commonly referred to as “drones”), or automated guided vehicles (AGV). In yet another example, by implementing communication device 5, wireless connectivity can also be provided at wireless access points or wireless hotspots.

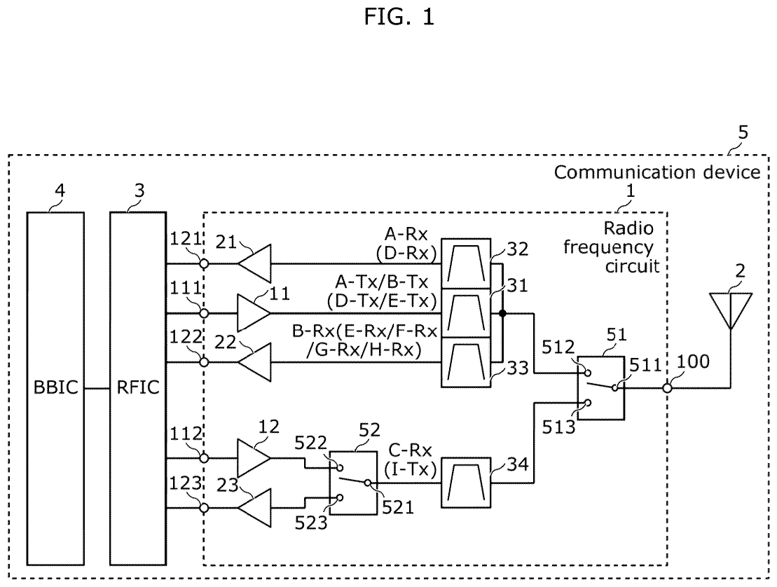

A circuit configuration of communication device 5 and radio frequency circuit 1 according to the present embodiment will be described with reference to FIG. 1. FIG. 1 illustrates a circuit configuration of communication device 5 according to the present embodiment.

Note that FIG. 1 illustrates an exemplary circuit configuration, and communication device 5 and radio frequency circuit 1 may be implemented using any of various types of circuit implementations and circuit technologies. Thus, the description of communication device 5 and radio frequency circuit 1 provided below should not be interpreted in a limited manner.

### 1.1 Circuit Configuration of Communication Device 5

First, a circuit configuration of communication device 5 according to the present embodiment will be described with reference to FIG. 1. Communication device 5 is implemented in a UE, and includes radio frequency circuit 1, antenna 2, radio frequency integrated circuit (RFIC) 3, and baseband integrated circuit (BBIC) 4.

Radio frequency circuit 1 can transfer radio frequency signals between antenna 2 and RFIC 3. A circuit configuration of radio frequency circuit 1 will be described later.

Antenna 2 is connected to antenna connection terminal 100 of radio frequency circuit 1. Antenna 2 can receive radio frequency signals from the outside of communication device 5 and supply the radio frequency signals to radio frequency circuit 1. Furthermore, antenna 2 can transmit radio frequency signals supplied from radio frequency circuit 1 to the outside of communication device 5. Note that antenna 2 need not be included in communication device 5. Communication device 5 may further include one or more antennas in addition to antenna 2.

RFIC 3 is an example of a signal processing circuit that processes radio frequency signals. Specifically, RFIC 3 can process radio frequency received signals input through a reception path of radio frequency circuit 1 by down-conversion, for instance, and supply received signals generated by processing the radio frequency received signals to BBIC 4. Furthermore, RFIC 3 can process transmission signals input from BBIC 4 by, for instance, up-conversion, and supply radio frequency transmission signals generated by processing the transmission signals to radio frequency circuit 1. RFIC 3 may include a controller (e.g., programmable circuitry such as a CPU that is configured to perform control operations by the circuitry's execution of stored computer code) configured to control, for instance, a switch and a power amplifier that are included in radio frequency circuit 1. Note that the controller may be partially or entirely provided outside of RFIC 3. For example, the controller may be partially or entirely provided in BBIC 4 or radio frequency circuit 1.

BBIC 4 is a baseband signal processing circuit that processes signals using a frequency band lower than a frequency of a radio frequency signal transferred by radio frequency circuit 1. A signal processed by BBIC 4 is used, for example, as an image signal for image display or as an audio signal for voice through a loudspeaker. Note that BBIC 4 need not be included in communication device 5.

### 1.2 Circuit Configuration of Radio Frequency Circuit 1

Next, a circuit configuration of radio frequency circuit 1 according to the present embodiment will be described with reference to FIG. 1. Radio frequency circuit 1 includes power amplifiers 11 and 12, low-noise amplifiers 21 to 23, filters 31 to 34, switches 51 and 52, antenna connection terminal 100, radio frequency input terminals 111 and 112, and radio frequency output terminals 121 to 123.

Antenna connection terminal 100 is an example of a first antenna connection terminal, and is an external connection terminal of radio frequency circuit 1. Specifically, antenna connection terminal 100 is connected to antenna 2 outside radio frequency circuit 1 and is connected to switch 51 inside radio frequency circuit 1. Accordingly, radio frequency circuit 1 can supply transmission signals to antenna 2 via antenna connection terminal 100, and can be supplied with received signals from antenna 2 via antenna connection terminal 100.

Radio frequency input terminals 111 and 112 are external connection terminals of radio frequency circuit 1. Specifically, radio frequency input terminals 111 and 112 are connected to RFIC 3 outside radio frequency circuit 1 and are connected to power amplifiers 11 and 12, respectively, inside radio frequency circuit 1. Radio frequency input terminal 111 can receive transmission signals in Bands A and B (and optionally Bands D and/or E) from RFIC 3. Radio frequency input terminal 112 can receive transmission signals in Band I from RFIC 3. Note that radio frequency input terminal 112 need not be included in radio frequency circuit 1.

Radio frequency output terminals 121 to 123 are external connection terminals of radio frequency circuit 1. Specifically, radio frequency output terminals 121 to 123 are connected to RFIC 3 outside radio frequency circuit 1 and are connected to low-noise amplifiers 21 to 23, respectively, inside radio frequency circuit 1. Radio frequency output terminal 121 can supply received signals in Band A (and optionally Band D) to RFIC 3. Radio frequency output terminal 122 can supply received signals in Band B (and optionally at least one of Band E, F, G, or H) to RFIC 3. Radio frequency output terminal 123 can supply received signals in Band C to RFIC 3.

The input end of power amplifier 11 is connected to radio frequency input terminal 111. The output end of power amplifier 11 is connected to filter 31. Power amplifier 11 can amplify transmission signals in Bands A and B (and optionally Bands D and/or E) received via radio frequency input terminal 111, using power supplied from a power supply (not illustrated).

The input end of power amplifier 12 is connected to radio frequency input terminal 112. The output end of power amplifier 12 is connected to filter 34 via switch 52. Power amplifier 12 can amplify transmission signals in Band I received via radio frequency input terminal 112, using power supplied from a power supply (not illustrated). Note that power amplifier 12 need not be included in radio frequency circuit 1.

Power amplifiers 11 and 12 can include heterojunction bipolar transistors (HBTs), and can be manufactured using semiconductor material. As the semiconductor material, silicon-germanium (SiGe) or gallium arsenide (GaAs) can be used, for example. Note that amplifier transistors of power amplifiers 11 and 12 are not limited to HBTs. For example, at least one of power amplifier 11 or power amplifier 12 may include a high electron mobility transistor (HEMT) or a metal-semiconductor field effect transistor (MESFET). In this case, gallium nitride (GaN) or silicon carbide (SiC) may be used as the semiconductor material.

Note that power amplifier 11 and/or power amplifier 12 need not be partially or entirely included in radio frequency circuit 1. In this case, power amplifier 11 may be connected between RFIC 3 and radio frequency input terminal 111, and power amplifier 12 may be connected between RFIC 3 and radio frequency input terminal 112. Power amplifier 11 and/or power amplifier 12 may be partially or entirely included in RFIC 3.

The input end of low-noise amplifier 21 is connected to filter 32. The output end of low-noise amplifier 21 is connected to radio frequency output terminal 121. Low-noise amplifier 21 can amplify received signals in Band A (and optionally Band D) that have passed through filter 32, by using power supplied from a power supply (not illustrated).

The input end of low-noise amplifier 22 is connected to filter 33. The output end of low-noise amplifier 22 is connected to radio frequency output terminal 122. Low-noise amplifier 22 can amplify received signals in Band B (and optionally at least one of Band E, F, G, or H) that have passed through filter 33, by using power supplied from a power supply (not illustrated).

The input end of low-noise amplifier 23 is connected to filter 34 via switch 52. The output end of low-noise amplifier 23 is connected to radio frequency output terminal 123. Low-noise amplifier 23 can amplify received signals in Band C that have passed through filter 34, by using power supplied from a power supply (not illustrated).

Low-noise amplifiers 21 to 23 can include field effect transistors (FETs), and can be manufactured using a semiconductor material. As the semiconductor material, for example, monocrystalline silicon, GaN, or SiC can be used. Note that amplifier transistors of low-noise amplifiers 21 to 23 are not limited to FETs. For example, one or more of low-noise amplifiers 21 to 23 may each include a bipolar transistor.

Note that low-noise amplifiers 21 to 23 need not be partially or entirely included in radio frequency circuit 1. In this case, low-noise amplifier 21 may be connected between radio frequency output terminal 121 and RFIC 3, low-noise amplifier 22 may be connected between radio frequency output terminal 122 and RFIC 3, and low-noise amplifier 23 may be connected between radio frequency output terminal 123 and RFIC 3. One or more of low-noise amplifiers 21 to 23 may be partially or entirely included in RFIC 3.

Filter 31 (A-Tx/B-Tx (D-Tx/E-Tx)) is an example of a first filter, and is a band-pass filter that includes passband PB1 including the uplink bands of Bands A and B. Note that passband PB1 of filter 31 may include the uplink bands of Bands D and/or E in addition to, or instead of, the uplink bands of Bands A and B. Filter 31 is connected between switch 51 and power amplifier 11. Specifically, one end of filter 31 is connected to terminal 512 of switch 51, and another end of filter 31 is connected to the output end of power amplifier 11.

Filter 32 (A-Rx (D-Rx)) is an example of a second filter, and is a band-pass filter that includes passband PB2 including the downlink band of Band A. Note that passband PB2 of filter 32 may include the downlink band of Band D in addition to, or instead of, the downlink band of Band A. Filter 32 is connected between switch 51 and low-noise amplifier 21. Specifically, one end of filter 32 is connected to terminal 512 of switch 51, and another end of filter 32 is connected to the input end of low-noise amplifier 21.

Filter 33 (B-Rx (E-Rx/F-Rx/G-Rx/H-Rx)) is an example of a third filter, and is a band-pass filter that includes passband PB3 including the downlink band of Band B. Note that passband PB3 of filter 33 may include the downlink band of Band E, R, G, or H, or any combination thereof, in addition to, or instead of, the downlink band of Band B. Filter 33 is connected between switch 51 and low-noise amplifier 22. Specifically, one end of filter 33 is connected to terminal 512 of switch 51, and another end of filter 33 is connected to the input end of low-noise amplifier 22.

Filter 34 (C-Rx (I-Tx)) is an example of a fourth filter, and is a band-pass filter that includes a passband including the downlink band of Band C. Note that the passband of filter 34 may include the uplink band of Band I in addition to the downlink band of Band C. Filter 34 is connected between (i) switch 51 and (ii) power amplifier 12 and low-noise amplifier 23. Specifically, one end of filter 34 is connected to terminal 513 of switch 51, and another end of filter 34 is connected via switch 52 to the output end of power amplifier 12 and the input end of low-noise amplifier 23. Note that when the passband of filter 34 does not include the uplink band of Band I, filter 34 need not be connected to power amplifier 12. In this case, power amplifier 12 and switch 52 need not be included in radio frequency circuit 1.

Switch 51 is connected between antenna connection terminal 100 and filters 31 to 34. Specifically, switch 51 includes terminals 511 to 513. Terminal 511 is an example of a first terminal, and is connected to antenna connection terminal 100. Terminal 512 is an example of a second terminal, and is connected to filters 31 to 33. Terminal 513 is an example of a third terminal, and is connected to filter 34.

With such a connection configuration, switch 51 can connect terminal 511 exclusively to terminal 512 or can connect terminal 511 exclusively to terminal 513, based on a control signal from RFIC 3, for example. Stated differently, switch 51 can switch between connecting terminal 511 only to terminal 512 or connecting terminal 511 only to terminal 513. Switch 51 includes a single-pole double-throw (SPDT) switch circuit, for example.

Switch 52 is connected between (i) filter 34 and (ii) power amplifier 12 and low-noise amplifier 23. Specifically, switch 52 includes terminals 521 to 523. Terminal 521 is connected to filter 34. Terminal 522 is connected to the output end of power amplifier 12. Terminal 523 is connected to the input end of low-noise amplifier 23.

With such a connection configuration, switch 52 can connect terminal 521 exclusively to terminal 522 or can connect terminal 521 exclusively to terminal 523, based on a control signal from RFIC 3, for example. In other words, switch 52 can switch between connecting terminal 521 only to terminal 522 or connecting terminal 521 only to terminal 523. Switch 52 includes an SPDT switch circuit, for example. Note that switch 52 need not be included in radio frequency circuit 1.

### 1.3 Specific Example of Frequency Bands

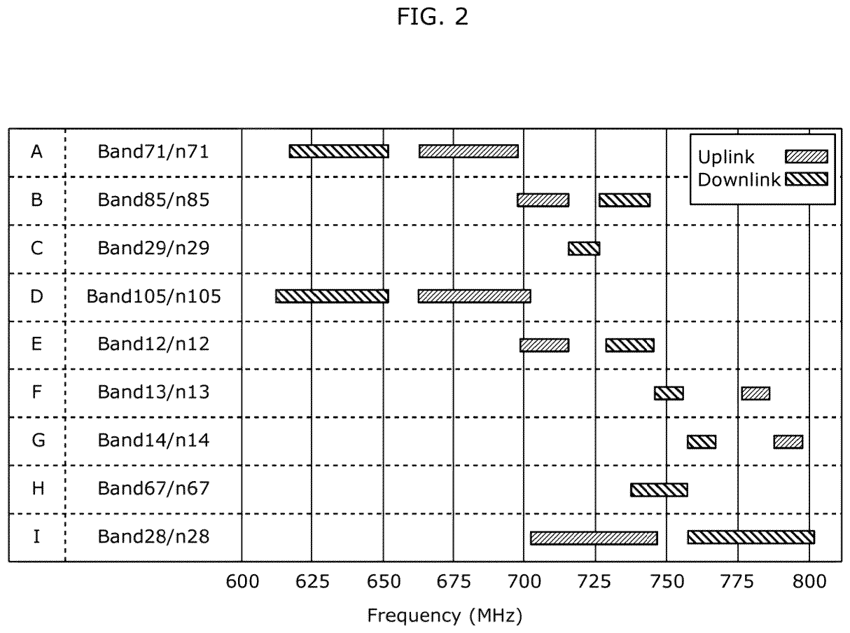

Here, a specific example of frequency bands related to communication device 5 according to the present embodiment will be described with reference to FIG. 2. FIG. 2 illustrates a specific example of frequency bands related to communication device 5 according to the present embodiment. In FIG. 2, the vertical axis shows band names, and the horizontal axis shows frequencies (MHz).

Bands A to I are frequency bands for a communication system established by using radio access technology (RAT), and are predefined by standardizing bodies (such as 3GPP and IEEE, for example). Examples of the communication system include a 5th Generation New Radio (5G NR) system, a Long Term Evolution (LTE) system, and a Wireless Local Area Network (WLAN) system.

Band A is an example of a first band and is an FDD band that includes an uplink band and a downlink band. In Band A, the downlink band is lower than the uplink band. In the present embodiment, Band 71 for LTE or n71 for 5G NR (DL: 617-652 MHz, UL: 663-698 MHz) is used as Band A, but Band A is not limited thereto.

Band B is an example of a second band and is an FDD band that includes an uplink band and a downlink band. Signals of Band B and signals of Band A can be simultaneously communicated. Stated differently, the combination of Band A and Band B is a band combination for simultaneous communication. In Band B, the downlink band is higher than the uplink band. The uplink band of Band B is higher than the uplink band of Band A. In the present embodiment, Band 85 for LTE or n85 for 5G NR (DL: 728-746 MHz, UL: 698-716 MHz) is used as Band B, but Band B is not limited thereto.

Band C is an example of a third band and is an SDL band that includes only a downlink band. A configuration in which signals of Band C and signals of Band A can be simultaneously communicated is possible. Stated differently, the combination of Band A and Band C may be a band combination for simultaneous communication. The downlink band of Band C is higher than the uplink band of Band B and lower than the downlink band of Band B. In the present embodiment, Band 29 for LTE or n29 for 5G NR (DL: 717-728 MHz) is used as Band C, but Band C is not limited thereto.

Band D is an FDD band that includes an uplink band and a downlink band. In Band D, the downlink band is lower than the uplink band. In the present embodiment, Band 105 for LTE or n105 for 5G NR (DL: 612-652 MHz, UL: 663-703 MHz) is used as Band D, but Band D is not limited thereto.

Band E is an FDD band that includes an uplink band and a downlink band. In Band E, the downlink band is higher than the uplink band. In the present embodiment, Band 12 for LTE or n12 for 5G NR (DL: 729-746 MHz, UL: 699-716 MHz) is used as Band E, but Band E is not limited thereto.

Band F is an FDD band or SDL band that includes at least a downlink band. The downlink band of Band F is higher than the uplink band of Band B and higher than the downlink band of Band C. In the present embodiment, Band 13 for LTE or n13 for 5G NR (DL: 746-756 MHz, UL: 777-787 MHz) is used as Band F, but Band F is not limited thereto.

Band G is an FDD band or SDL band that includes at least a downlink band. The downlink band of Band G is higher than the uplink band of Band B and higher than the downlink band of Band C. In the present embodiment, Band 14 for LTE or n14 for 5G NR (DL: 758-768 MHz, UL: 788-798 MHz) is used as Band G, but Band G is not limited thereto.

Band H is an FDD band or SDL band that includes at least a downlink band. The downlink band of Band H is higher than the uplink band of Band B and higher than the downlink band of Band C. In the present embodiment, Band 67 for LTE or n67 for 5G NR (DL: 738-758 MHz) is used as Band H, but Band H is not limited thereto.

Band I is an FDD band or SUL band that includes at least an uplink band. In the present embodiment, Band 28 for LTE or n28 for 5G NR (DL: 758-803 MHz, UL: 703-748 MHz) is used as Band I, but Band I is not limited thereto.

### 1.4 Pass Characteristic of Filters 31 to 33

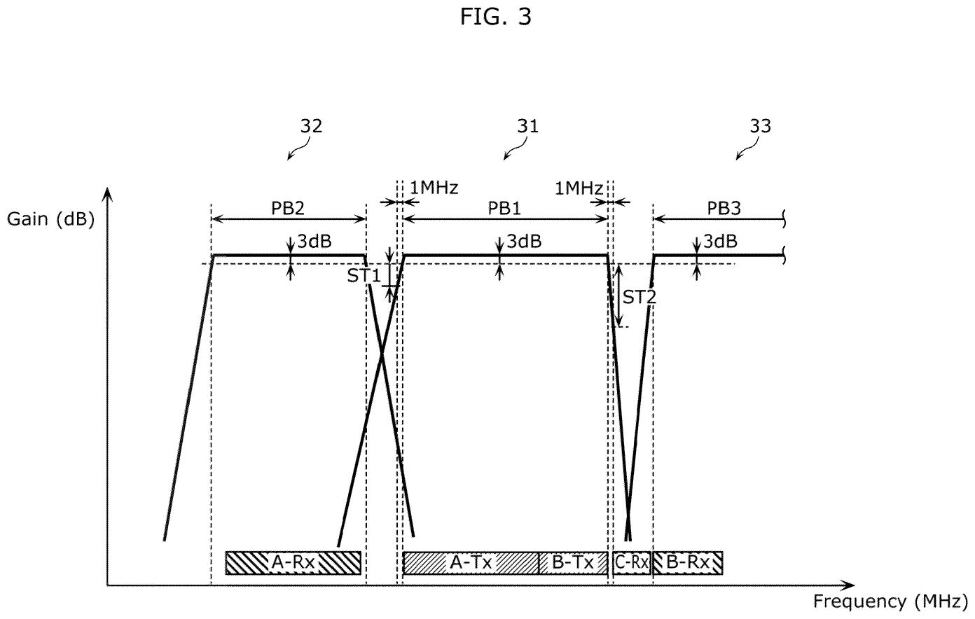

Next, the pass characteristic of filters 31 to 33 will be described with reference to FIG. 3. FIG. 3 illustrates a graph showing pass characteristics of filters 31 to 33 according to the present embodiment. In FIG. 3, frequency is shown on the horizontal axis and gain is shown on the vertical axis.

Passband PB1 of filter 31 includes the uplink band (A-Tx) of Band A and the uplink band (B-Tx) of Band B. More specifically, the low-frequency edge of passband PB1 is lower than the low-frequency edge of the uplink band of Band A. The high-frequency edge of passband PB1 is higher than the high-frequency edge of the uplink band of Band B.

Attenuation slope ST2 on the higher frequency side of passband PB1 of filter 31 is steeper than attenuation slope ST1 on the lower frequency side of passband PB1 of filter 31. Stated differently, the difference between the gain at the high-frequency edge of passband PB1 of filter 31 and the gain at a frequency 1 MHz higher than the high-frequency edge (=attenuation slope ST2) is greater than the difference between the gain at the low-frequency edge of passband PB1 of filter 31 and the gain at a frequency 1 MHz lower than the low-frequency edge (=attenuation slope ST1). This asymmetrical characteristic may be specifically designed to provide increased attenuation of transmission signals from Bands A and B at the frequencies corresponding to the downlink band of Band C, thereby mitigating interference.

Passband PB2 of filter 32 includes the downlink band (A-Rx) of Band A. More specifically, the low-frequency edge of passband PB2 is lower than the low-frequency edge of the downlink band of Band A. The high-frequency edge of passband PB2 is higher than the high-frequency edge of the downlink band of Band A.

Passband PB3 of filter 33 includes the downlink band (B-Rx) of Band B. More specifically, the low-frequency edge of passband PB3 is lower than the low-frequency edge of the downlink band of Band B. The high-frequency edge of passband PB3 is higher than the high-frequency edge of the downlink band of Band B.

### 1.5 Circuit Configuration of Filter 31

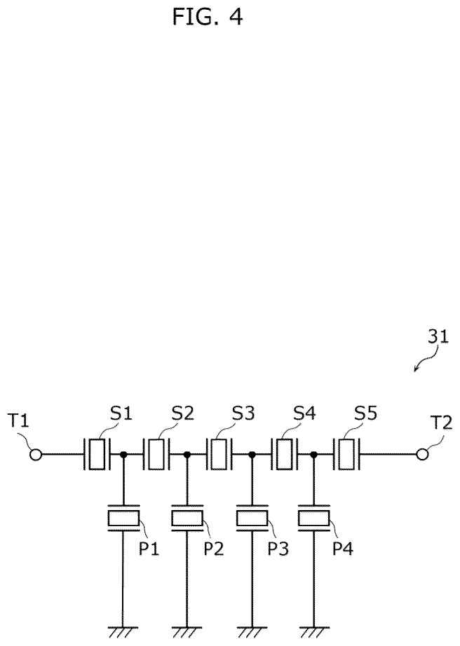

A circuit configuration of filter 31 that can achieve such pass characteristics will be described with reference to FIG. 4. FIG. 4 illustrates a circuit configuration of filter 31 according to the present embodiment.

Note that FIG. 4 illustrates an exemplary circuit configuration, and filter 31 may be implemented using any of various types of circuit implementations and circuit technologies. Thus, the description of filter 31 provided below should not be interpreted in a limited manner.

Filter 31 is an acoustic wave filter, and includes input-output terminals T1 and T2, series arm resonators S1 to S5, and a plurality of parallel arm resonators P1 to P4.

The plurality of series arm resonators S1 to S5 are connected in series between input-output terminals T1 and T2. The plurality of parallel arm resonators P1 to P4 are connected in parallel to each other between a path connecting input-output terminals T1 and T2 and the ground. With such a connection configuration of series arm resonators S1 to S5 and the plurality of parallel arm resonators P1 to P4, filter 31 forms a ladder-type bandpass filter. Filter 31 functions as a bandpass filter including passband PB1 and attenuation bands on the lower frequency side and the higher frequency side of passband PB1.

Note that the number of series arm resonators and the number of parallel arm resonators included in filter 31 are not limited to 5 and 4, respectively. For example, the number of series arm resonators and the number of parallel arm resonators included in filter 31 may both be 1. Stated differently, filter 31 may include at least one series arm resonator and at least one parallel arm resonator. Also, filter 31 need not be an acoustic wave filter.

### 1.6 Basic Structure of Resonators

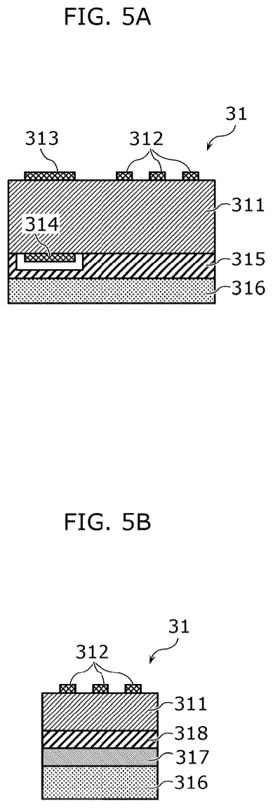

Next, the basic structure of the plurality of series arm resonators S1 to S5 and the plurality of parallel arm resonators P1 to P4 that constitute filter 31 will be described with reference to FIG. 5A.

FIG. 5A illustrates a cross-sectional view of filter 31 according to the present embodiment. Filter 31 includes piezoelectric layer 311, interdigital transducer (IDT) electrodes 312, upper electrode 313, lower electrode 314, silicon dioxide layer 315, and support substrate 316.

Piezoelectric layer 311 can propagate surface acoustic waves (SAW) between IDT electrodes 312 that are formed on its main surface. Furthermore, piezoelectric layer 311 can propagate bulk acoustic waves (BAW) between upper electrode 313 and lower electrode 314. Piezoelectric layer 311 includes, for example, a piezoelectric single crystal or piezoelectric ceramics of lithium tantalate (LiTaO₃), lithium niobate (LiNbO₃), aluminum nitride (AlN), or zinc oxide (ZnO). Note that the material of piezoelectric layer 311 is not limited thereto.

IDT electrodes 312 are formed on the main surface of piezoelectric layer 311 and can generate and detect surface acoustic waves. IDT electrodes 312 include, for example, aluminum (Al), titanium (Ti), gold (Au), silver (Ag), copper (Cu), platinum (Pt), tungsten (W), molybdenum (Mo), ruthenium (Ru), or any combination thereof. Note that the material of IDT electrodes 312 is not limited thereto.

Upper electrode 313 and lower electrode 314 are formed on the upper surface and lower surface of piezoelectric layer 311, respectively, and can generate and detect bulk waves. Upper electrode 313 and lower electrode 314 include, similar to IDT electrodes 312, for example, Al, Ti, Au, Ag, Cu, Pt, W, Mo, Ru, or any combination thereof. Note that the material of upper electrode 313 and lower electrode 314 is not limited thereto.

Silicon dioxide layer 315 functions as a spacer for providing a hollow structure around lower electrode 314. More specifically, silicon dioxide layer 315 includes a recess, on the piezoelectric layer 311 side, in which lower electrode 314 is accommodated. This creates sufficient space for lower electrode 314 to vibrate.

Support substrate 316 is disposed below silicon dioxide layer 315 and piezoelectric layer 311, and can support silicon dioxide layer 315 and piezoelectric layer 311. Support substrate 316 includes silicon (Si), quartz, or sapphire, for example. Note that the material of support substrate 316 is not limited thereto.

With the basic structure of FIG. 5A, filter 31 can be realized that includes a plurality of series arm resonators S1 to S5 as surface acoustic wave (SAW) resonators, and includes a plurality of parallel arm resonators P1 to P4 as bulk acoustic wave (BAW) resonators. Note that not all of the plurality of parallel arm resonators P1 to P4 need to be BAW resonators, and it is sufficient if at least one of the plurality of parallel arm resonators P1 to P4 is a BAW resonator.

Note that the basic structure of series arm resonators and parallel arm resonators of filter 31 is not limited to the structure illustrated in FIG. 5A. For example, in filter 31, the series arm resonator and the parallel arm resonator may both be SAW resonators. In such cases, filter 31 need not include upper electrode 313, lower electrode 314, silicon dioxide layer 315, support substrate 316, or any combination thereof. A variation of this filter 31 will be described with reference to FIG. 5B.

FIG. 5B illustrates a cross-sectional view of a variation of filter 31 according to the present embodiment. In FIG. 5B, filter 31 is a laminated SAW filter that includes piezoelectric layer 311, IDT electrodes 312, support substrate 316, high acoustic velocity layer 317, and low acoustic velocity layer 318.

Piezoelectric layer 311 is an example of a first piezoelectric layer and a second piezoelectric layer, and can propagate surface acoustic waves between IDT electrodes 312 that are formed on its main surface. Piezoelectric layer 311 includes, for example, a piezoelectric single crystal or piezoelectric ceramics of LiTaO₃, LiNbO₃, AlN, or ZnO. Note that the material of piezoelectric layer 311 is not limited thereto.

IDT electrodes 312 are formed on the main surface of piezoelectric layer 311, similarly to FIG. 5A, and can generate and detect surface acoustic waves. IDT electrodes 312 include, for example, Al, Ti, Au, Ag, Cu, Pt, W, Mo, Ru, or any combination thereof. Note that the material of IDT electrodes 312 is not limited thereto.

Support substrate 316 is disposed below high acoustic velocity layer 317, low acoustic velocity layer 318, and piezoelectric layer 311, and can support high acoustic velocity layer 317, low acoustic velocity layer 318, and piezoelectric layer 311. The velocity of a bulk wave propagating in support substrate 316 may be higher than the velocity of an acoustic wave (for example, a surface wave and a boundary wave) propagating in piezoelectric layer 311. Support substrate 316, similarly to Embodiment 1, includes Si, quartz, or sapphire, for example. Note that the material of support substrate 316 is not limited thereto.

High acoustic velocity layer 317 is an example of a first high acoustic velocity layer and a second high acoustic velocity layer, and is disposed below piezoelectric layer 311. In FIG. 5B, high acoustic velocity layer 317 is disposed between support substrate 316 and low acoustic velocity layer 318. High acoustic velocity layer 317 can confine the surface acoustic wave generated by IDT electrodes 312 to the portion where piezoelectric layer 311 and low acoustic velocity layer 318 are layered, and prevent the surface acoustic wave from leaking to layers below high acoustic velocity layer 317. The velocity of a bulk wave propagating in high acoustic velocity layer 317 is higher than the velocity of an acoustic wave such as a surface wave or a boundary wave propagating in piezoelectric layer 311. High acoustic velocity layer 317 includes, for example, aluminum nitride (AlN), silicon nitride (SiN), aluminum oxide (AlO), silicon carbide (SiC), silicon oxynitride (SiON), sapphire, or diamond. Note that the material of high acoustic velocity layer 317 is not limited thereto.

Low acoustic velocity layer 318 is disposed below piezoelectric layer 311. In FIG. 5B, low acoustic velocity layer 318 is disposed between high acoustic velocity layer 317 and piezoelectric layer 311. The velocity of a bulk wave propagating in low acoustic velocity layer 318 is lower than the velocity of an acoustic wave (for example, a surface wave and a boundary wave) propagating in piezoelectric layer 311. Since acoustic wave energy inherently has the property of concentrating in a medium with low acoustic velocity, the layered structure of low acoustic velocity layer 318 and high acoustic velocity layer 317 can effectively inhibit the surface acoustic wave generated by IDT electrodes 312 from leaking to the outside. Low acoustic velocity layer 318 includes silicon dioxide (SiO₂), for example. Note that the material of low acoustic velocity layer 318 is not limited thereto.

Note that the basic structure of series arm resonators and parallel arm resonators of filter 31 is not limited to the structure illustrated in FIG. 5B. For example, filter 31 need not include low acoustic velocity layer 318. Even in this case, the surface acoustic wave generated by IDT electrodes 312 can be inhibited from leaking to the outside. In filter 31 and/or filter 32, high acoustic velocity layer 317 and support substrate 316 may be integrated.

High acoustic velocity layer 317 and low acoustic velocity layer 318 may be a high impedance layer and a low impedance layer, respectively. The high impedance layer has a characteristic acoustic impedance higher than that of the low impedance layer. Conversely, the low impedance layer has a characteristic acoustic impedance lower than that of the high impedance layer. Even in such a case, the surface acoustic wave can be confined, and the surface acoustic wave can be inhibited from leaking to the outside.

### 1.7 Communication Modes of Communication Device 5

Next, a plurality of communication modes available in communication device 5 will be described.

### 1.7.1 First Communication Mode

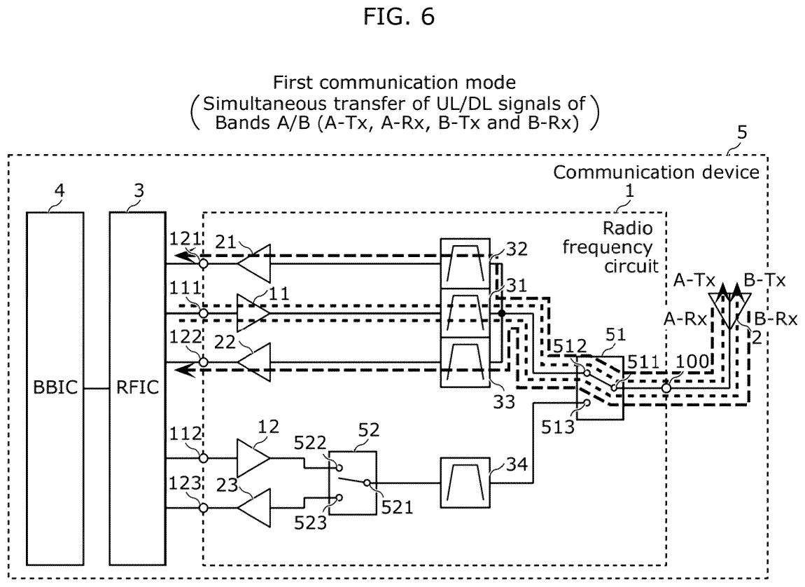

First, the first communication mode will be described with reference to FIG. 6. FIG. 6 illustrates the first communication mode of communication device 5 according to the present embodiment. In the following figures, broken line arrows represent the flow of radio frequency signals.

In the first communication mode, communication device 5 can transmit and/or receive at least one of the uplink signals or the downlink signals of Bands A and B. In FIG. 6, communication device 5 simultaneously transmits and receives all of the uplink and downlink signals of Bands A and B. As illustrated in FIG. 6, in the first communication mode, switch 51 connects terminal 511 to terminal 512 and not terminal 513. With this, filters 31 to 33 are connected to antenna connection terminal 100.

As a result, the transmission signals of Bands A and B are transferred from RFIC 3 to antenna 2 via radio frequency input terminal 111, power amplifier 11, filter 31, switch 51, and antenna connection terminal 100. The received signal of Band A is transferred from antenna 2 to RFIC 3 via antenna connection terminal 100, switch 51, filter 32, low-noise amplifier 21, and radio frequency output terminal 121. The received signal of Band B is transferred from antenna 2 to RFIC 3 via antenna connection terminal 100, switch 51, filter 33, low-noise amplifier 22, and radio frequency output terminal 122.

Note that in the first communication mode, some of the uplink signals and downlink signals of Bands A and B need not be transmitted and/or received.

### 1.7.2 Second Communication Mode

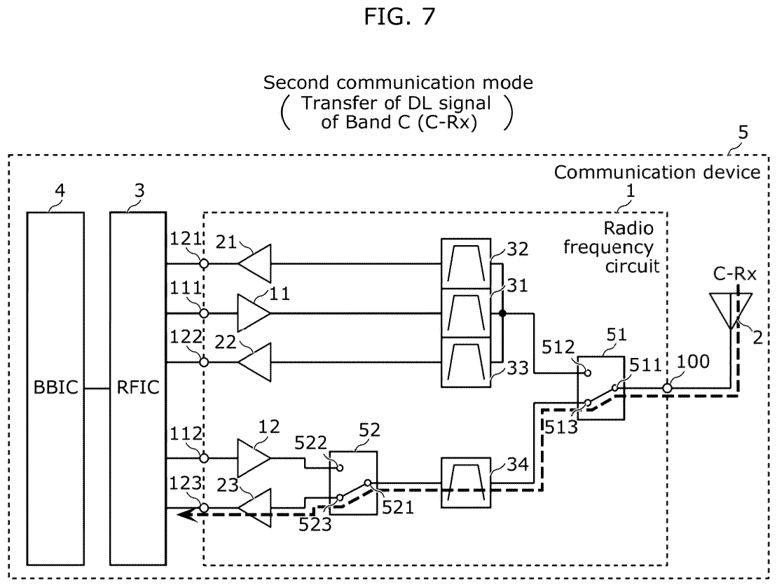

Next, a second communication mode will be described with reference to FIG. 7. FIG. 7 illustrates the second communication mode of communication device 5 according to the present embodiment.

In the second communication mode, communication device 5 can receive the downlink signal of Band C. As illustrated in FIG. 7, in the second communication mode, switch 51 connects terminal 511 to terminal 513 and not terminal 512. With this, filter 34 is connected to antenna connection terminal 100.

As a result, the received signal of Band C is transferred from antenna 2 to RFIC 3 via antenna connection terminal 100, switch 51, filter 34, switch 52, low-noise amplifier 23, and radio frequency output terminal 123.

### 1.8 Advantageous Effects, Etc.

As described above, radio frequency circuit 1 according to the present embodiment includes: filter 31 having passband PB1 that includes the uplink band of Band A and the uplink band of Band B; filter 32 having passband PB2 that includes the downlink band of Band A; filter 33 having passband PB3 that includes the downlink band of Band B; filter 34 having a passband that includes the downlink band of Band C; and switch 51 that includes terminal 511 connected to antenna connection terminal 100, terminal 512 connected to filters 31, 32, and 33, and terminal 513 connected to filter 34. The combination of Bands A and B is a band combination for simultaneous communication. The uplink band of Band A is higher than the downlink band of Band A. The uplink band of Band B is higher than the uplink band of Band A. The downlink band of Band B is higher than the uplink band of Band B. The downlink band of Band C is higher than the uplink band of Band B and lower than the downlink band of Band B. Filter 31 has a steeper attenuation slope on a higher frequency side of passband PB1 than on a lower frequency side of passband PB1.

With this, since the uplink bands of Bands A and B are included in passband PB1 of filter 31, transmission of signals of Bands A and B can be supported with one filter 31, whereby the number of filters included in radio frequency circuit 1 can be reduced. When the uplink bands of Bands A and B are included in passband PB1 of filter 31 to reduce the number of filters in this way, it becomes difficult to satisfy the spurious emission requirements set for the downlink band of Band C in transmission of signals of Band A. Therefore, by increasing the attenuation slope on the higher frequency side of filter 31, the spurious emission requirements set for the downlink band of Band C can also be satisfied, which is effective for reducing the number of filters.

For example, in radio frequency circuit 1 according to the present embodiment, switch 51 may be configured to connect terminal 511 exclusively to terminal 512, or to connect terminal 511 exclusively to terminal 513.

With this, since terminal 512 connected to filter 31 and terminal 513 connected to filter 34 are not simultaneously connected to terminal 511, filter 31 can be prevented from being connected to the reception path of Band C, whereby the quality of the received signal of Band C (for example, noise figure (NF) can be improved).

For example, in radio frequency circuit 1 according to the present embodiment, in a first communication mode that simultaneously transfers at least two of: a signal of the uplink band of Band A; a signal of the downlink band of Band A; a signal of the uplink band of Band B; or a signal of the downlink band of Band B, switch 51 may be configured to connect terminal 511 to terminal 512 and not terminal 513, and in a second communication mode that transfers a signal of the downlink band of Band C, switch 51 may be configured to connect terminal 511 to terminal 513 and not terminal 512.

With this, since filter 31 is not connected to the reception path of Band C in the second communication mode, degradation of the quality of the received signal of Band C can be inhibited.

For example, in radio frequency circuit 1 according to the present embodiment, filter 31 may be an acoustic wave filter that includes at least one series arm resonator S1 to S5 and at least one parallel arm resonator P1 to P4, the at least one series arm resonator S1 to S5 may include a SAW resonator, and the at least one parallel arm resonator P1 to P4 may include a BAW resonator.

With this, since BAW resonators are used for at least one of parallel arm resonators P1 to P4, a higher quality factor (Q value) can be achieved, and the attenuation slope on the higher frequency side of passband PB1 can be increased even more.

For example, in radio frequency circuit 1 according to the present embodiment, filter 31 may include piezoelectric layer 311 on which IDT electrodes 312 are formed, and high acoustic velocity layer 317 disposed below piezoelectric layer 311. Moreover, the velocity of a bulk wave propagating in high acoustic velocity layer 317 is higher than the velocity of an acoustic wave propagating in piezoelectric layer 311.

With this, a high Q value can be achieved through the confinement effect of acoustic waves within high acoustic velocity layer 317, and the attenuation slope on the higher frequency side of passband PB1 can be increased.

For example, in radio frequency circuit 1 according to the present embodiment, Band A may be Band 71 for LTE or n71 for 5G NR, Band B may be Band 85 for LTE or n85 for 5G NR, and Band C may be Band 29 for LTE or n29 for 5G NR.

With this, in LTE or 5G NR, the number of filters for the uplink bands of Band 71 or n71 and Band 85 or n85 can be reduced, and degradation of the quality of the received signal of Band 29 or n29 caused by this can be inhibited.

For example, in radio frequency circuit 1 according to the present embodiment, passband PB1 of filter 31 may further include an uplink band of at least one of: Band 12 for LTE; Band 105 for LTE; n12 for 5G NR; or n105 for 5G NR.

With this, further reduction in the number of filters can be realized.

For example, in radio frequency circuit 1 according to the present embodiment, passband PB2 of filter 32 may further include a downlink band of at least one of Band 105 for LTE or n105 for 5G NR.

With this, further reduction in the number of filters can be realized.

For example, in radio frequency circuit 1 according to the present embodiment, passband PB3 of filter 33 may further include a downlink band of at least one of: Band 12 for LTE; Band 13 for LTE; Band 14 for LTE; Band 67 for LTE; n12 for 5G NR; n13 for 5G NR; n14 for 5G NR; or n67 for 5G NR.

With this, further reduction in the number of filters can be realized.

For example, in radio frequency circuit 1 according to the present embodiment, the passband of filter 34 may further include an uplink band of at least one of Band 28 for LTE or n28 for 5G NR.

With this, further reduction in the number of filters can be realized.

### Variation of Embodiment 1

Next, a variation of Embodiment 1 will be described. Communication device 5A according to the present variation includes two antennas and is mainly different from communication device 5 according to Embodiment 1 in that it can simultaneously transmit and receive the uplink and downlink signals of Band A and the downlink signal of Band C. Hereinafter, the present variation will be described with reference to the drawings, focusing on different points from Embodiment 1.

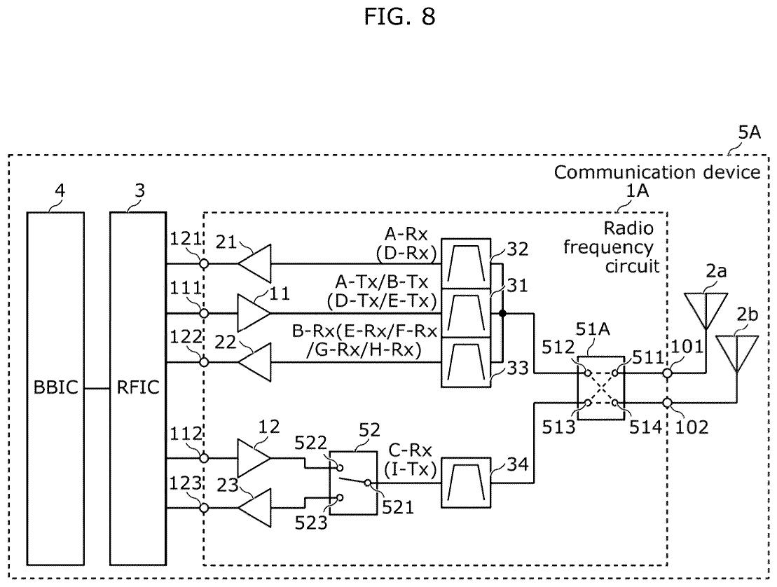

A circuit configuration of communication device 5A and radio frequency circuit 1A according to the present variation will be described with reference to FIG. 8. FIG. 8 illustrates a circuit configuration of communication device 5A according to the present variation.

Note that FIG. 8 illustrates an exemplary circuit configuration, and communication device 5A and radio frequency circuit 1A may be implemented using any of various types of circuit implementations and circuit technologies. Thus, the description of communication device 5A and radio frequency circuit 1A provided below should not be interpreted in a limited manner.

### 2.1 Circuit Configuration of Communication Device 5A

First, a circuit configuration of communication device 5A according to the present variation will be described with reference to FIG. 8. Communication device 5A includes radio frequency circuit 1A, antennas 2a and 2b, RFIC 3, and BBIC 4.

Radio frequency circuit 1A can transfer radio frequency signals between antennas 2a and 2b and RFIC 3. A circuit configuration of radio frequency circuit 1A will be described later.

Antenna 2a is connected to antenna connection terminal 101 of radio frequency circuit 1A. Antenna 2b is connected to antenna connection terminal 102 of radio frequency circuit 1A. Each of antennas 2a and 2b can receive radio frequency signals from the outside of communication device 5A and supply the radio frequency signals to radio frequency circuit 1A. Furthermore, each of antennas 2a and 2b can transmit radio frequency signals supplied from radio frequency circuit 1A to the outside of communication device 5A. Note that antenna 2a and/or 2b need not be included in communication device 5A. Communication device 5A may further include one or more antennas in addition to antennas 2a and 2b.

### 2.2 Circuit Configuration of Radio Frequency Circuit 1A

Next, a circuit configuration of radio frequency circuit 1A according to the present variation will be described with reference to FIG. 8. Radio frequency circuit 1A includes power amplifiers 11 and 12, low-noise amplifiers 21 to 23, filters 31 to 34, switches 51A and 52, antenna connection terminals 101 and 102, radio frequency input terminals 111 and 112, and radio frequency output terminals 121 to 123.

Antenna connection terminal 101 is an example of a first antenna connection terminal, and is an external connection terminal of radio frequency circuit 1A. Specifically, antenna connection terminal 101 is connected to antenna 2a outside radio frequency circuit 1A and is connected to switch 51A inside radio frequency circuit 1A. Accordingly, radio frequency circuit 1A can supply transmission signals to antenna 2a via antenna connection terminal 101, and can be supplied with received signals from antenna 2a via antenna connection terminal 101.

Antenna connection terminal 102 is an example of a second antenna connection terminal, and is an external connection terminal of radio frequency circuit 1A. Specifically, antenna connection terminal 102 is connected to antenna 2b outside radio frequency circuit 1A and is connected to switch 51A inside radio frequency circuit 1A. Accordingly, radio frequency circuit 1A can supply transmission signals to antenna 2b via antenna connection terminal 102, and can be supplied with received signals from antenna 2b via antenna connection terminal 102.

Switch 51A is connected between antenna connection terminals 101 and 102 and filters 31 to 34. Specifically, switch 51A includes terminals 511 to 514. Terminal 511 is an example of a first terminal, and is connected to antenna connection terminal 101. Terminal 512 is an example of a second terminal, and is connected to filters 31 to 33. Terminal 513 is an example of a third terminal, and is connected to filter 34. Terminal 514 is an example of a fourth terminal, and is connected to antenna connection terminal 102.

With such a connection configuration, switch 51A can connect terminals 511 and 514 to terminals 512 and 513 in a mutually exclusive manner, based on a control signal from RFIC 3, for example. Stated differently, switch 51A can connect terminal 511 to one of terminals 512 or 513, and terminal 514 to the other of terminals 512 or 513. Switch 51A includes a double-pole double-throw (DPDT) switch circuit, for example.

### 2.3 Communication Modes of Communication Device 5A

Next, a plurality of communication modes available in communication device 5A will be described. Communication device 5A can utilize a third communication mode in addition to the first communication mode and the second communication mode.

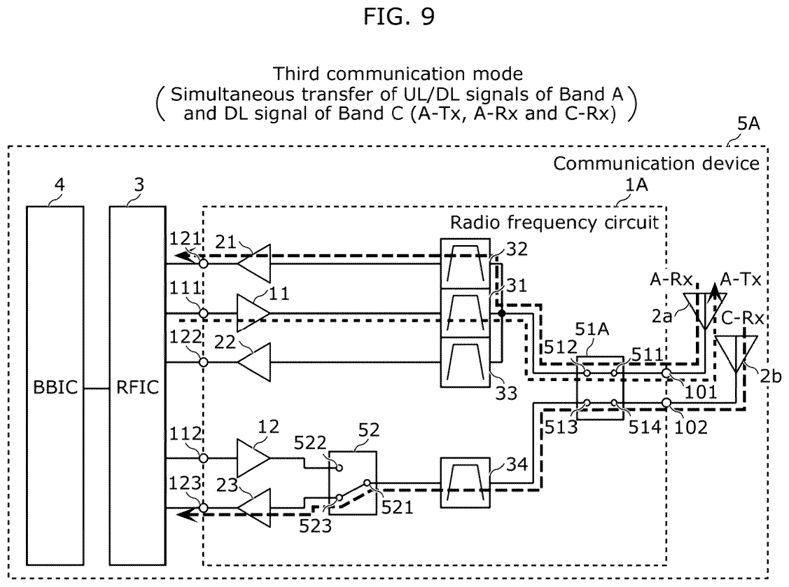

Here, a third communication mode will be described with reference to FIG. 9. FIG. 9 illustrates the third communication mode of communication device 5A according to the present variation. In the following figures, broken line arrows represent the flow of radio frequency signals.

In the third communication mode, communication device 5A can simultaneously transmit and receive or receive at least one of the uplink signal or the downlink signal of Band A and the downlink signal of Band C. In FIG. 9, communication device 5A simultaneously transmits and receives both the uplink and downlink signals of Band A and the downlink signal of Band C. As illustrated in FIG. 9, in the third communication mode, switch 51A connects terminal 511 to terminal 512 and connects terminal 514 to terminal 513. Accordingly, filters 31 to 33 are connected to antenna connection terminal 101, and filter 34 is connected to antenna connection terminal 102.

As a result, the transmission signal of Band A is transferred from RFIC 3 to antenna 2a via radio frequency input terminal 111, power amplifier 11, filter 31, switch 51A, and antenna connection terminal 101. The received signal of Band A is transferred from antenna 2a to RFIC 3 via antenna connection terminal 101, switch 51A, filter 32, low-noise amplifier 21, and radio frequency output terminal 121. The received signal of Band C is transferred from antenna 2b to RFIC 3 via antenna connection terminal 102, switch 51A, filter 34, switch 52, low-noise amplifier 23, and radio frequency output terminal 123.

### 2.4 Advantageous Effects, Etc.

As described above, in radio frequency circuit 1A according to the present variation, the combination of Bands A and C may be a band combination for simultaneous communication, and switch 51A may further include terminal 514 connected to antenna connection terminal 102.

With this, filters 31 to 34 can be connected to two antennas 2a and 2b, and simultaneous communication by the band combination of Bands A and C can be supported.

For example, in radio frequency circuit 1A according to the present variation, in a third communication mode that simultaneously transfers (i) at least one of a signal of the uplink band of Band A or a signal of the downlink band of Band A and (ii) a signal of the downlink band of Band C, switch 51A may be configured to connect terminal 511 to terminal 512 and not terminal 513, and connect terminal 514 to terminal 513 and not terminal 512.

Accordingly, in the third communication mode, filter 31 is connected to antenna connection terminal 101 (antenna 2a), and filter 34 is connected to antenna connection terminal 102 (antenna 2b). Therefore, signals of Bands A and C can be transmitted and received without connecting filter 31 to the reception path of Band C, and degradation of the quality of the received signal of Band C can be inhibited.

### Embodiment 2

Next, Embodiment 2 will be described. In the present embodiment, the main difference from Embodiment 1 is the use of a variable band filter for filtering the uplink bands of Bands A and B. Hereinafter, the present embodiment will be described with reference to the drawings, focusing on different points from Embodiment 1.

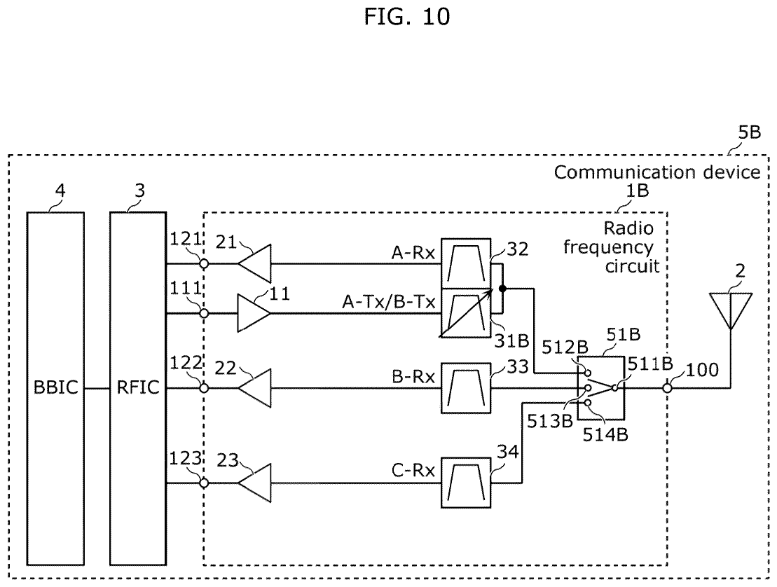

A circuit configuration of communication device 5B and radio frequency circuit 1B according to the present embodiment will be described with reference to FIG. 10. FIG. 10 illustrates a circuit configuration of communication device 5B according to the present embodiment.

Note that FIG. 10 illustrates an exemplary circuit configuration, and communication device 5B and radio frequency circuit 1B may be implemented using any of various types of circuit implementations and circuit technologies. Thus, the description of communication device 5B and radio frequency circuit 1B provided below should not be interpreted in a limited manner.

Note that the circuit configuration of communication device 5B is similar to the circuit configuration of communication device 5 according to Embodiment 1 except that radio frequency circuit 1B is included instead of radio frequency circuit 1, and thus description thereof is omitted.

### 3.1 Circuit Configuration of Radio Frequency Circuit 1B

A circuit configuration of radio frequency circuit 1B according to the present embodiment will be described with reference to FIG. 10. Radio frequency circuit 1B includes power amplifier 11, low-noise amplifiers 21 to 23, filters 31B and 32 to 34, switch 51B, antenna connection terminal 100, radio frequency input terminal 111, and radio frequency output terminals 121 to 123.

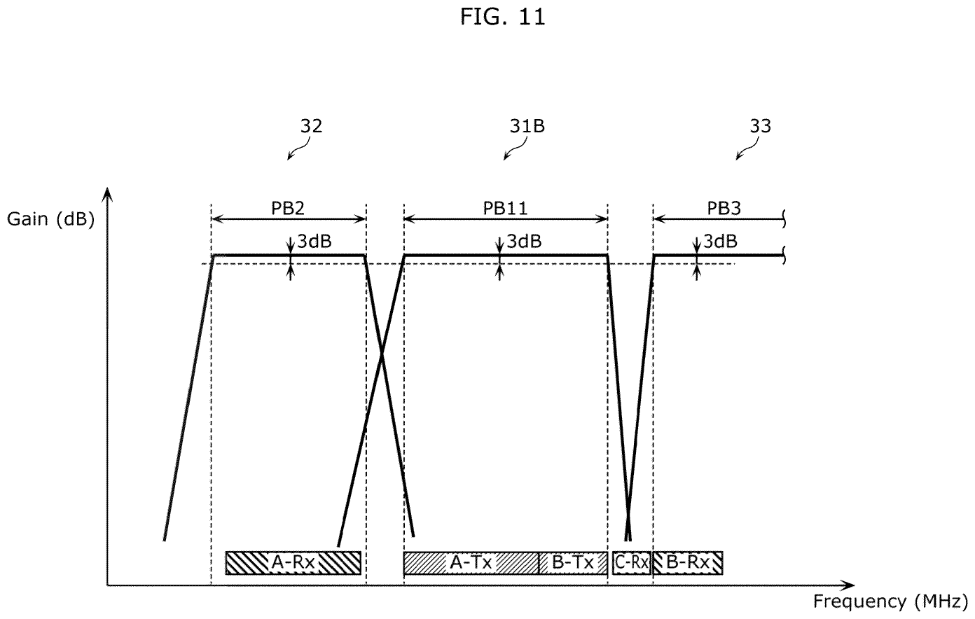

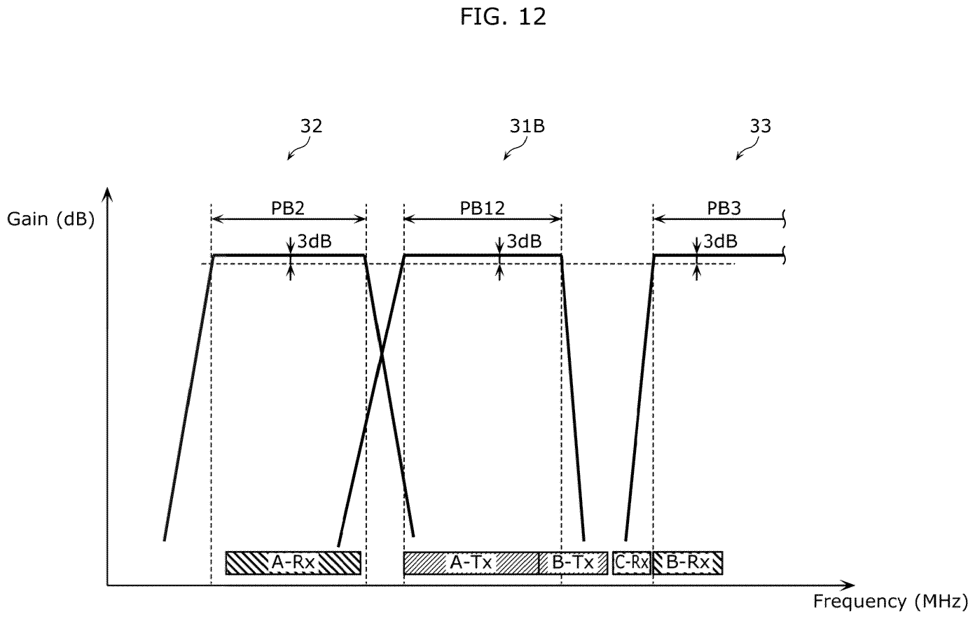

Filter 31B (A-Tx/B-Tx) is an example of a first filter, and is a band-pass filter adjustable to at least two passbands PB11 and PB12. Filter 31B is connected between switch 51B and power amplifier 11. Specifically, one end of filter 31B is connected to terminal 512B of switch 51B, and another end of filter 31B is connected to the output end of power amplifier 11. Note that passbands PB11 and PB12 will be described later with reference to FIG. 11 and FIG. 12.

Filter 32 (A-Rx) is an example of a second filter, and is a band-pass filter that includes passband PB2. Filter 32 is connected between switch 51B and low-noise amplifier 21. Specifically, one end of filter 32 is connected to terminal 512B of switch 51B, and another end of filter 32 is connected to the input end of low-noise amplifier 21.

Filter 33 (B-Rx) is an example of a third filter, and is a band-pass filter that includes passband PB3. Filter 33 is connected between switch 51B and low-noise amplifier 22. Specifically, one end of filter 33 is connected to terminal 513B of switch 51B, and another end of filter 33 is connected to the input end of low-noise amplifier 22.

Filter 34 (C-Rx) is an example of a fourth filter, and is a band-pass filter that includes a passband including the downlink band of Band C. Filter 34 is connected between switch 51B and low-noise amplifier 23. Specifically, one end of filter 34 is connected to terminal 514B of switch 51B, and another end of filter 34 is connected to the input end of low-noise amplifier 23.

Switch 51B is connected between antenna connection terminal 100 and filters 31B and 32 to 34. Specifically, switch 51B includes terminals 511B to 514B. Terminal 511B is an example of a first terminal, and is connected to antenna connection terminal 100. Terminal 512B is an example of a second terminal, and is connected to filters 31B and 32. Terminal 513B is an example of a third terminal, and is connected to filter 33. Terminal 514B is an example of a fourth terminal, and is connected to filter 34.

With such a connection configuration, switch 51B can connect terminal 511B to at least one of terminals 512B to 514B, based on a control signal from RFIC 3, for example. Stated differently, switch 51B can connect terminal 511B to any combination of terminals 512B to 514B. Switch 51B includes a multi-connection type switch circuit, for example.

### 3.2 Pass Characteristic of Filter 31B

Next, the pass characteristic of filter 31B will be described with reference to FIG. 11 and FIG. 12. FIG. 11 and FIG. 12 illustrate a graph showing pass characteristics of filters 31B, 32, and 33 according to the present embodiment. In FIG. 11 and FIG. 12, frequency is shown on the horizontal axis and gain is shown on the vertical axis.

Passband PB11 of filter 31B is an example of a first passband, and as illustrated in FIG. 11, includes the uplink band (A-Tx) of Band A and the uplink band (B-Tx) of Band B. More specifically, the low-frequency edge of passband PB11 is lower than the low-frequency edge of the uplink band of Band A, and the high-frequency edge of passband PB11 is higher than the high-frequency edge of the uplink band of Band B. Also, similar to passband PB1 of filter 31, the attenuation slope on the higher frequency side of passband PB11 of filter 31B is steeper than the attenuation slope on the lower frequency side of passband PB11 of filter 31B.

Passband PB12 of filter 31B is an example of a second passband, and as illustrated in FIG. 12, includes the uplink band (A-Tx) of Band A. More specifically, the low-frequency edge of passband PB12 is lower than the low-frequency edge of the uplink band of Band A, and the high-frequency edge of passband PB12 is higher than the high-frequency edge of the uplink band of Band A. Passband PB12 is narrower than passband PB11. More specifically, the high-frequency edge of passband PB12 is lower than the high-frequency edge of passband PB11.

### 3.3 Communication Modes of Communication Device 5B

Next, a plurality of communication modes available in communication device 5B will be described.

### 3.3.1 First Communication Mode

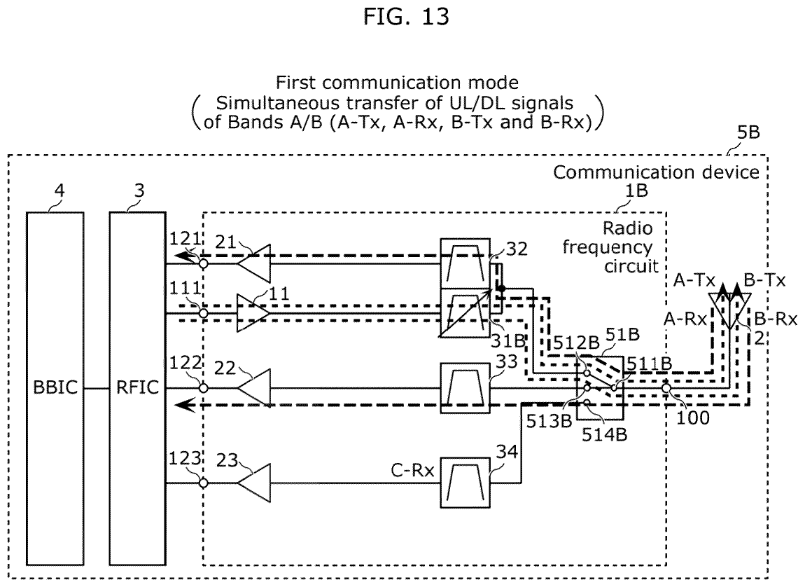

First, a first communication mode will be described with reference to FIG. 13. FIG. 13 illustrates the first communication mode of communication device 5B according to the present embodiment.

In the first communication mode, communication device 5B can transmit and/or receive at least one of the uplink signals or the downlink signals of Bands A and B. In FIG. 13, communication device 5B simultaneously transmits and receives all of the uplink and downlink signals of Bands A and B. As illustrated in FIG. 13, in the first communication mode, switch 51B connects terminal 511B to terminals 512B and 513B and not terminal 514B. With this, filters 31B, 32 and 33 are connected to antenna connection terminal 100. Here, filter 31B is adjusted to passband PB11 of FIG. 11.

As a result, the transmission signals of Bands A and B are transferred from RFIC 3 to antenna 2 via radio frequency input terminal 111, power amplifier 11, filter 31B, switch 51B, and antenna connection terminal 100. The received signal of Band A is transferred from antenna 2 to RFIC 3 via antenna connection terminal 100, switch 51B, filter 32, low-noise amplifier 21, and radio frequency output terminal 121. The received signal of Band B is transferred from antenna 2 to RFIC 3 via antenna connection terminal 100, switch 51B, filter 33, low-noise amplifier 22, and radio frequency output terminal 122.

Note that in the first communication mode, some of the uplink signals and downlink signals of Bands A and B need not be transmitted and/or received.

### 3.3.2 Second Communication Mode

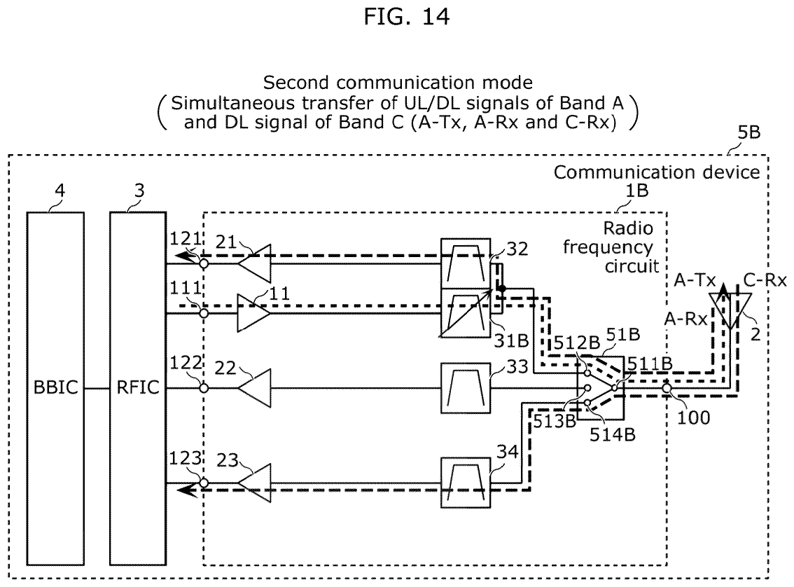

Next, a second communication mode will be described with reference to FIG. 14. FIG. 14 illustrates the second communication mode of communication device 5B according to the present embodiment.

In the second communication mode, communication device 5B can simultaneously transmit and receive or receive at least one of the uplink signal or the downlink signal of Band A and the downlink signal of Band C. In FIG. 14, communication device 5B simultaneously transmits and receives both the uplink and downlink signals of Band A and the downlink signal of Band C. As illustrated in FIG. 14, in the second communication mode, switch 51B connects terminal 511B to terminals 512B and 514B and does not connect terminal 511B to terminal 513B. With this, filters 31B, 32 and 34 are connected to antenna connection terminal 100. Here, filter 31B is adjusted to passband PB12 of FIG. 12.

As a result, the transmission signal of Band A is transferred from RFIC 3 to antenna 2 via radio frequency input terminal 111, power amplifier 11, filter 31B, switch 51B, and antenna connection terminal 100. The received signal of Band A is transferred from antenna 2 to RFIC 3 via antenna connection terminal 100, switch 51B, filter 32, low-noise amplifier 21, and radio frequency output terminal 121. The received signal of Band C is transferred from antenna 2 to RFIC 3 via antenna connection terminal 100, switch 51B, filter 34, low-noise amplifier 23, and radio frequency output terminal 123.

### 3.4 Advantageous Effects, Etc.

As described above, radio frequency circuit 1B according to the present embodiment includes: filter 31B adjustable to passband PB11 that includes the uplink band of Band A and the uplink band of Band B, and passband PB12 that includes the uplink band of Band A and is narrower than passband PB11; filter 32 having a passband that includes the downlink band of Band A; filter 33 having a passband that includes the downlink band of Band B; filter 34 having a passband that includes the downlink band of Band C; and switch 51B that includes terminal 511B connected to antenna connection terminal 100, terminal 512B connected to filter 31B and filter 32, terminal 513B connected to filter 33, and terminal 514B connected to filter 34. A combination of Bands A and B is a band combination for simultaneous communication. The uplink band of Band A is higher than the downlink band of Band A. The uplink band of Band B is higher than the uplink band of Band A. The downlink band of Band B is higher than the uplink band of Band B. The downlink band of Band C is higher than the uplink band of Band B and lower than the downlink band of Band B. Filter 31B has a steeper attenuation slope on a higher frequency side of passband PB11 than on a lower frequency side of passband PB11.

With this, since the uplink bands of Bands A and B are included in passband PB11 of filter 31B, transmission of signals of Bands A and B can be supported with one filter 31B, whereby the number of filters included in radio frequency circuit 1B can be reduced. When the uplink bands of Bands A and B are included in passband PB11 of filter 31B to reduce the number of filters in this way, it becomes difficult to satisfy the spurious emission requirements set for the downlink band of Band C in transmission of signals of Band A. Therefore, by increasing the attenuation slope on the higher frequency side of filter 31B, the spurious emission requirements set for the downlink band of Band C can also be satisfied, which is effective for reducing the number of filters. Since filter 31B can be adjusted to the narrower passband PB12, degradation of the quality of the received signal of Band C can be inhibited in simultaneous transmission and reception of the uplink signal of Band A and the downlink signal of Band C.

For example, in radio frequency circuit 1B according to the present embodiment, in a first communication mode that simultaneously transfers (i) at least one of: a signal of the uplink band of Band A; a signal of the downlink band of Band A; or a signal of the uplink band of Band B and (ii) a signal of the downlink band of Band B, switch 51B may be configured to connect terminal 511B to terminal 512B and terminal 513B and not terminal 514B, and filter 31B may be adjusted to passband PB11, and in a second communication mode that simultaneously transfers (i) at least one of a signal of the uplink band of Band A or a signal of the downlink band of Band A and (ii) a signal of the downlink band of Band C, switch 51B may be configured to connect terminal 511B to terminal 512B and terminal 514B and not terminal 513B, and filter 31B may be adjusted to passband PB12.

With this, since filter 31B is adjusted to passband PB12 in the second communication mode, interference of the transmission signal of Band A with the received signal of Band C can be inhibited, and degradation of the quality of the received signal of Band C can be inhibited.

For example, in radio frequency circuit 1B according to the present embodiment, Band A may be Band 71 for LTE or n71 for 5G NR, Band B may be Band 85 for LTE or n85 for 5G NR, and Band C may be Band 29 for LTE or n29 for 5G NR.

With this, in LTE or 5G NR, the number of filters for the uplink bands of Band 71 or n71 and Band 85 or n85 can be reduced, and degradation of the quality of the received signal of Band 29 or n29 caused by this can be inhibited.

### Embodiment 3

Next, Embodiment 3 will be described. In the present embodiment, the main difference from Embodiment 2 is the use of a variable band filter for filtering the downlink bands of Bands B and C. Hereinafter, the present embodiment will be described with reference to the drawings, focusing on different points from Embodiments 1 and 2.

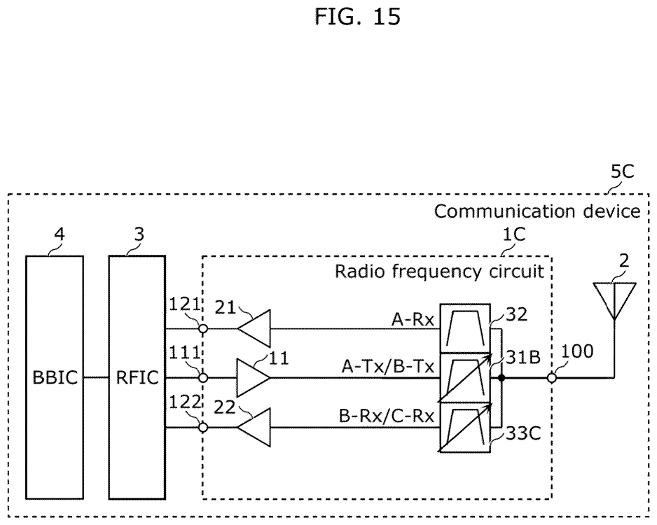

A circuit configuration of communication device 5C and radio frequency circuit 1C according to the present embodiment will be described with reference to FIG. 15. FIG. 15 illustrates a circuit configuration of communication device 5C according to the present embodiment.

Note that FIG. 15 illustrates an exemplary circuit configuration, and communication device 5C and radio frequency circuit 1C may be implemented using any of various types of circuit implementations and circuit technologies. Thus, the description of communication device 5C and radio frequency circuit 1C provided below should not be interpreted in a limited manner.

Note that the circuit configuration of communication device 5C is similar to the circuit configuration of communication device 5 according to Embodiment 1 except that radio frequency circuit 1C is included instead of radio frequency circuit 1, and thus description thereof is omitted.

### 4.1 Circuit Configuration of Radio Frequency Circuit 1C

A circuit configuration of radio frequency circuit 1C according to the present embodiment will be described with reference to FIG. 15. Radio frequency circuit 1C includes power amplifier 11, low-noise amplifiers 21 and 22, filters 31B, 32 and 33C, antenna connection terminal 100, radio frequency input terminal 111, and radio frequency output terminals 121 and 122.

Filter 31B (A-Tx/B-Tx) is an example of a first filter, and is a band-pass filter adjustable to at least two passbands PB11 and PB12. Filter 31B is connected between antenna connection terminal 100 and power amplifier 11. Specifically, one end of filter 31B is connected to antenna connection terminal 100, and another end of filter 31B is connected to the output end of power amplifier 11.

Filter 32 (A-Rx) is an example of a second filter, and is a band-pass filter that includes passband PB2. Filter 32 is connected between antenna connection terminal 100 and low-noise amplifier 21. Specifically, one end of filter 32 is connected to antenna connection terminal 100, and another end of filter 32 is connected to the input end of low-noise amplifier 21.

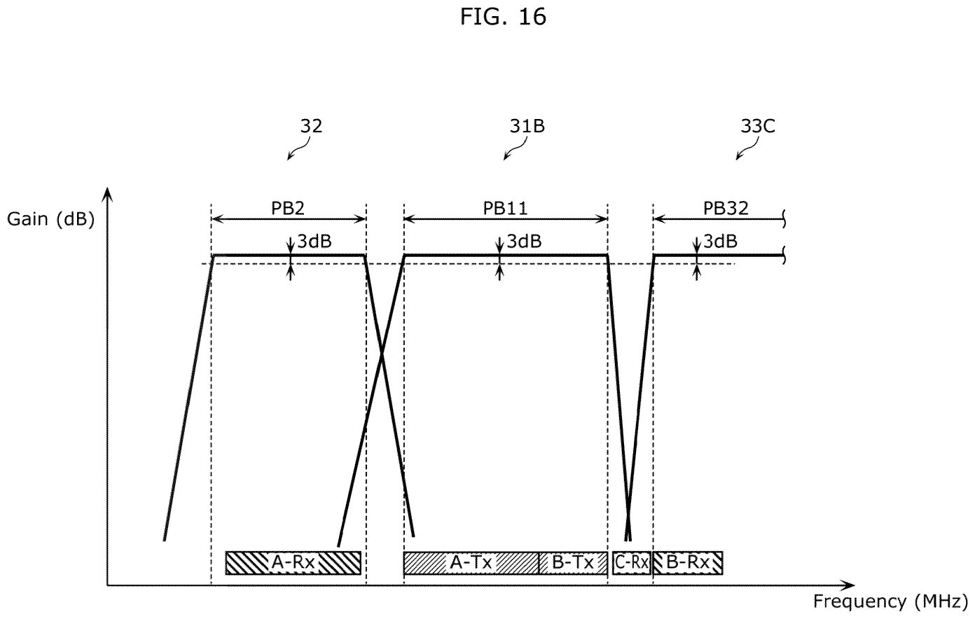

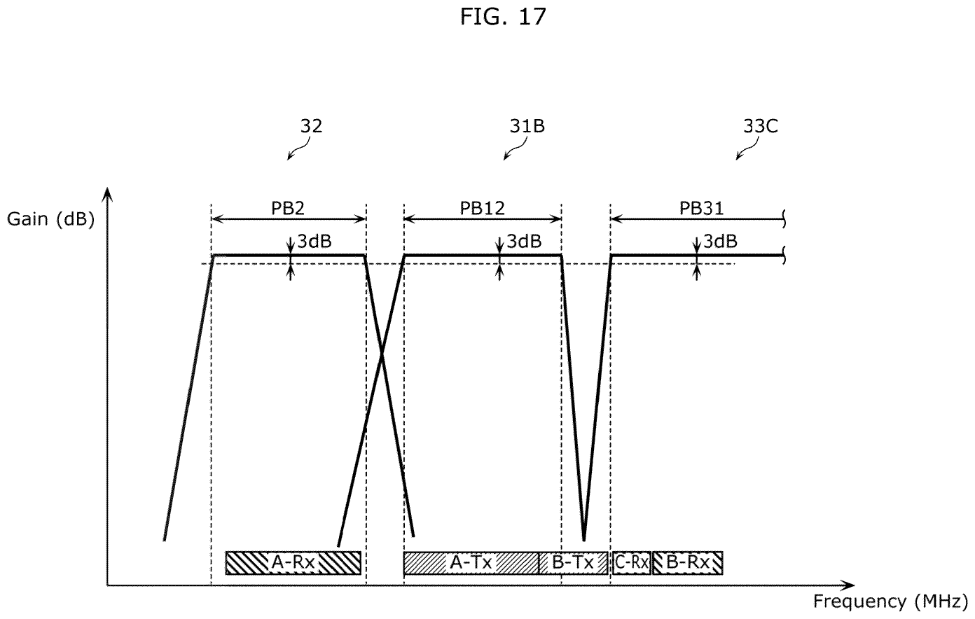

Filter 33C (B-Rx/C-Rx) is an example of a third filter, and is a band-pass filter adjustable to at least two passbands PB31 and PB32. Filter 33C is connected between antenna connection terminal 100 and low-noise amplifier 22. Specifically, one end of filter 33C is connected to antenna connection terminal 100, and another end of filter 33C is connected to the input end of low-noise amplifier 22. Note that passbands PB31 and PB32 will be described later with reference to FIG. 16 and FIG. 17.

### 4.2 Pass Characteristic of Filter 33C

Next, the pass characteristic of filter 33C will be described with reference to FIG. 16 and FIG. 17. FIG. 16 and FIG. 17 illustrate a graph showing pass characteristics of filters 31B, 32, and 33C according to the present embodiment. In FIG. 16 and FIG. 17, frequency is shown on the horizontal axis and gain is shown on the vertical axis.

Passband PB31 of filter 33C is an example of a third passband, and as illustrated in FIG. 17, includes the downlink band (C-Rx) of Band C and the downlink band (B-Rx) of Band B. More specifically, the low-frequency edge of passband PB31 is lower than the low-frequency edge of the downlink band of Band C. The high-frequency edge of passband PB31 is higher than the high-frequency edge of the downlink band of Band B.

Passband PB32 of filter 33C is an example of a fourth passband, and as illustrated in FIG. 16, includes the downlink band (B-Rx) of Band B. More specifically, the low-frequency edge of passband PB32 is lower than the low-frequency edge of the downlink band of Band B, and the high-frequency edge of passband PB32 is higher than the high-frequency edge of the downlink band of Band B. Passband PB32 is narrower than passband PB31. More specifically, the low-frequency edge of passband PB32 is higher than the low-frequency edge of passband PB31.

### 4.3 Communication Modes of Communication Device 5C

Next, a plurality of communication modes available in communication device 5C will be described.

### 4.3.1 First Communication Mode

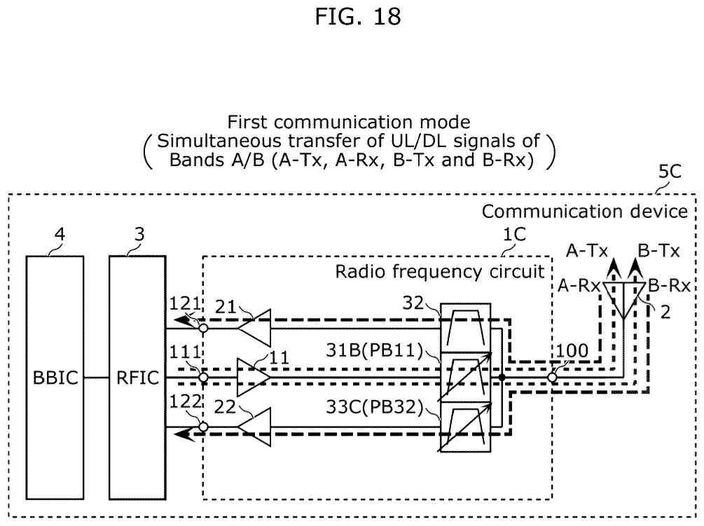

First, a first communication mode will be described with reference to FIG. 18. FIG. 18 illustrates the first communication mode of communication device 5C according to the present embodiment.

In the first communication mode, communication device 5C can transmit and/or receive at least one of the uplink signals or the downlink signals of Bands A and B. In FIG. 18, communication device 5C simultaneously transmits and receives all of the uplink and downlink signals of Bands A and B. As illustrated in FIG. 18, in the first communication mode, filter 31B is adjusted to passband PB11 of FIG. 16, and filter 33C is adjusted to passband PB32 of FIG. 16.

As a result, the transmission signals of Bands A and B are transferred from RFIC 3 to antenna 2 via radio frequency input terminal 111, power amplifier 11, filter 31B, and antenna connection terminal 100. The received signal of Band A is transferred from antenna 2 to RFIC 3 via antenna connection terminal 100, filter 32, low-noise amplifier 21, and radio frequency output terminal 121. The received signal of Band B is transferred from antenna 2 to RFIC 3 via antenna connection terminal 100, filter 33C, low-noise amplifier 22, and radio frequency output terminal 122.

Note that in the first communication mode, some of the uplink signals and downlink signals of Bands A and B need not be transmitted and/or received.

### 4.3.2 Second Communication Mode

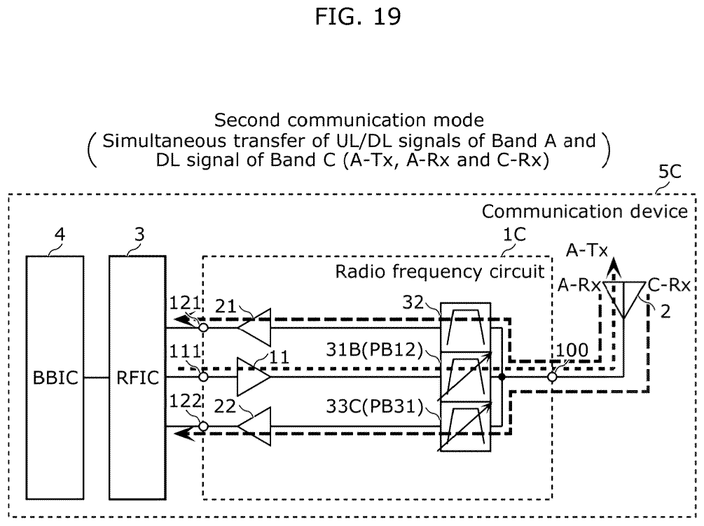

Next, a second communication mode will be described with reference to FIG. 19. FIG. 19 illustrates the second communication mode of communication device 5C according to the present embodiment.

In the second communication mode, communication device 5C can simultaneously transmit and receive or receive at least one of the uplink signal or the downlink signal of Band A and the downlink signal of Band C. In FIG. 19, communication device 5C simultaneously transmits and receives both the uplink and downlink signals of Band A and the downlink signal of Band C. As illustrated in FIG. 19, in the second communication mode, filter 31B is adjusted to passband PB12 of FIG. 17, and filter 33C is adjusted to passband PB31 of FIG. 17.

As a result, the transmission signal of Band A is transferred from RFIC 3 to antenna 2 via radio frequency input terminal 111, power amplifier 11, filter 31B, and antenna connection terminal 100. The received signal of Band A is transferred from antenna 2 to RFIC 3 via antenna connection terminal 100, filter 32, low-noise amplifier 21, and radio frequency output terminal 121. The received signal of Band C is transferred from antenna 2 to RFIC 3 via antenna connection terminal 100, filter 33C, low-noise amplifier 22, and radio frequency output terminal 122.

### 4.4 Advantageous Effects, Etc.

As described above, radio frequency circuit 1C according to the present embodiment includes: filter 31B adjustable to passband PB11 that includes the uplink band of Band A and the uplink band of Band B, and passband PB12 that includes the uplink band of Band A and is narrower than passband PB11; filter 32 having a passband that includes the downlink band of Band A; filter 33C adjustable to passband PB31 that includes the downlink band of Band B and the downlink band of Band C, and passband PB32 that includes the downlink band of Band B and is narrower than passband PB31. A combination of Bands A and B is a band combination for simultaneous communication. The uplink band of Band A is higher than the downlink band of Band A. The uplink band of Band B is higher than the uplink band of Band A. The downlink band of Band B is higher than the uplink band of Band B. The downlink band of Band C is higher than the uplink band of Band B and lower than the downlink band of Band B. Filter 31B has a steeper attenuation slope on a higher frequency side of passband PB11 than on a lower frequency side of passband PB11.

With this, since the uplink bands of Bands A and B are included in passband PB11 of filter 31B, transmission of signals of Bands A and B can be supported with one filter 31B, whereby the number of filters included in radio frequency circuit 1C can be reduced. Furthermore, since the downlink bands of Bands B and C are included in passband PB31 of filter 33C, reception of signals of Bands B and C can be supported with one filter 33C, whereby the number of filters included in radio frequency circuit 1C can be reduced. When the uplink bands of Bands A and B are included in passband PB11 of filter 31B to reduce the number of filters in this way, it becomes difficult to satisfy the spurious emission requirements set for the downlink band of Band C in transmission of signals of Band A. Therefore, by increasing the attenuation slope on the higher frequency side of filter 31B, the spurious emission requirements set for the downlink band of Band C can also be satisfied, which is effective for reducing the number of filters. Since filter 31B can be adjusted to the narrower passband PB12, degradation of the quality of the received signal of Band C can be inhibited in simultaneous transmission and reception of the uplink signal of Band A and the downlink signal of Band C. Furthermore, since filter 33C can be adjusted to the narrower passband PB32, degradation of the quality of the received signal of Band B can be inhibited.

For example, in radio frequency circuit 1C according to the present embodiment, in a first communication mode that simultaneously transfers at least two of: a signal of the uplink band of Band A; a signal of the downlink band of Band A; a signal of the uplink band of Band B; or a signal of the downlink band of Band B: filter 31B may be adjusted to passband PB11, and filter 33C may be adjusted to passband PB32. In a second communication mode that simultaneously transfers (i) at least one of a signal of the uplink band of Band A or a signal of the downlink band of Band A and (ii) a signal of the downlink band of Band C: filter 31B may be adjusted to passband PB12, and filter 33C may be adjusted to passband PB31.

With this, since filter 31B is adjusted to passband PB12 in the second communication mode, interference of the transmission signal of Band A with the received signal of Band C can be inhibited, and degradation of the quality of the received signal of Band C can be inhibited. Furthermore, since filter 33C is adjusted to passband PB32 in the first communication mode, interference of the transmission signal of Band B with the received signal of Band B can be inhibited, and degradation of the quality of the received signal of Band B can be inhibited.

For example, in radio frequency circuit 1C according to the present embodiment, Band A may be Band 71 for LTE or n71 for 5G NR, Band B may be Band 85 for LTE or n85 for 5G NR, and Band C may be Band 29 for LTE or n29 for 5G NR.

With this, in LTE or 5G NR, the number of filters for the uplink bands of Band 71 or n71 and Band 85 or n85 can be reduced, and degradation of the quality of the received signal of Band 29 or n29 caused by this can be inhibited.

### Other Embodiments

Although the above has described a radio frequency circuit according to one aspect of the present disclosure based on the embodiments, the radio frequency circuit according to the present disclosure is not limited to the above embodiments. The present disclosure also encompasses another embodiment achieved by combining arbitrary elements in the above embodiments, variations resulting from applying, to the embodiments, various modifications that may be conceived by those skilled in the art within a range that does not depart from the scope of the present disclosure, and various devices that each include the radio frequency circuit. As described herein, a radio frequency circuit includes a first filter having a first passband that includes an uplink band of a first band and an uplink band of a second band; a second filter having a passband that includes a downlink band of the first band; and a downlink filter arrangement that filters the downlink band of the second band and the downlink band of a third band. This downlink filter arrangement is configured to selectively pass signals in these bands. For example, the downlink filter arrangement may comprise a third filter and a fourth filter connected to an antenna terminal via a switch, as shown in Embodiments 1 and 2. Alternatively, the downlink filter arrangement may be implemented as a single adjustable filter capable of passing one or both of the downlink bands, as shown in Embodiment 3. Further, all filter paths are ultimately communicatively coupled to an antenna terminal, either directly or via a switch. Finally, the first filter has a steeper attenuation slope on its high-frequency side.

For example, in the circuit configurations of the radio frequency circuits according to the above embodiments, another circuit element and a line, for instance, may be provided between circuit elements and paths connecting signal paths disclosed in the drawings. For example, an impedance matching circuit may be provided between a power amplifier and/or a low-noise amplifier and a filter. An impedance matching circuit can be provided with an inductor and/or a capacitor, for example, but is not limited to such a configuration.

For example, communication devices 5B and/or 5C according to Embodiment 2 and/or 3 may, similarly to Embodiment 1, support transmission and/or reception of some or all of Bands D to I.

Note that Bands A to I described in the above embodiments are examples and are not limited to FIG. 2. For example, in the radio frequency circuits according to the above embodiments, Band A may be Band 105 for LTE or n105 for 5G NR, Band B may be Band 28 for LTE or n28 for 5G NR, and Band C may be Band 13 for LTE or n13 for 5G NR.

Below are features of the radio frequency circuit described based on the above embodiments.
<1>

A radio frequency circuit including:
a first filter having a passband that includes an uplink band of a first band and an uplink band of a second band;
a second filter having a passband that includes a downlink band of the first band;
a third filter having a passband that includes a downlink band of the second band;
a fourth filter having a passband that includes a downlink band of a third band; and
a switch that includes a first terminal connected to a first antenna connection terminal, a second terminal connected to the first filter, the second filter, and the third filter, and a third terminal connected to the fourth filter, wherein
a combination of the first band and the second band is a band combination for simultaneous communication,
the uplink band of the first band is higher than the downlink band of the first band,
the uplink band of the second band is higher than the uplink band of the first band,
the downlink band of the second band is higher than the uplink band of the second band,
the downlink band of the third band is higher than the uplink band of the second band and lower than the downlink band of the second band, and
the first filter has a steeper attenuation slope on a higher frequency side of the passband than on a lower frequency side of the passband.
<2>

The radio frequency circuit according to <1>, wherein
the switch is configured to connect the first terminal exclusively to the second terminal, or to connect the first terminal exclusively to the third terminal.
<3>

The radio frequency circuit according to <2>, wherein
in a first communication mode that simultaneously transfers at least two of: a signal of the uplink band of the first band; a signal of the downlink band of the first band; a signal of the uplink band of the second band; or a signal of the downlink band of the second band, the switch is configured to connect the first terminal to the second terminal and not the third terminal, and
in a second communication mode that transfers a signal of the downlink band of the third band, the switch is configured to connect the first terminal to the third terminal and not the second terminal.
<4>

The radio frequency circuit according to any one of <1> to <3>, wherein
the first filter is an acoustic wave filter that includes at least one series arm resonator and at least one parallel arm resonator,
the at least one series arm resonator includes a surface acoustic wave (SAW) resonator, and
the at least one parallel arm resonator includes a bulk acoustic wave (BAW) resonator.
<5>

The radio frequency circuit according to any one of <1> to <3>, wherein
the first filter includes:
   a first piezoelectric layer on which an interdigital transducer (IDT) electrode is provided; and
   a first high acoustic velocity layer disposed below the first piezoelectric layer, wherein a velocity of a bulk wave propagating in the first high acoustic velocity layer is higher than a velocity of an acoustic wave propagating in the first piezoelectric layer.
<6>

The radio frequency circuit according to any one of <1> to <5>, wherein
the first band is Band 71 for LTE or n71 for 5G NR,
the second band is Band 85 for LTE or n85 for 5G NR, and
the third band is Band 29 for LTE or n29 for 5G NR.
<7>

The radio frequency circuit according to <6>, wherein
the passband of the first filter further includes an uplink band of at least one of: Band 12 for LTE; Band 105 for LTE; n12 for 5G NR; or n105 for 5G NR.
<8>

The radio frequency circuit according to <6> or <7>, wherein
the passband of the second filter further includes a downlink band of at least one of Band 105 for LTE or n105 for 5G NR.
<9>

The radio frequency circuit according to any one of <6> to <8>, wherein
the passband of the third filter further includes a downlink band of at least one of: Band 12 for LTE; Band 13 for LTE; Band 14 for LTE; Band 67 for LTE; n12 for 5G NR; n13 for 5G NR; n14 for 5G NR; or n67 for 5G NR.
<10>

The radio frequency circuit according to any one of <6> to <9>, wherein
the passband of the fourth filter further includes an uplink band of at least one of Band 28 for LTE or n28 for 5G NR.
<11>

The radio frequency circuit according to any one of <1> to <5>, wherein
the first band is Band 105 for LTE or n105 for 5G NR,
the second band is Band 28 for LTE or n28 for 5G NR, and
the third band is Band 13 for LTE or n13 for 5G NR.
<12>

The radio frequency circuit according to any one of <1> to <11>, wherein
a combination of the first band and the third band is a band combination for simultaneous communication, and
the switch further includes a fourth terminal connected to a second antenna connection terminal.
<13>

The radio frequency circuit according to <12>, wherein
in a third communication mode that simultaneously transfers (i) at least one of a signal of the uplink band of the first band or a signal of the downlink band of the first band and (ii) a signal of the downlink band of the third band, the switch is configured to connect the first terminal to the second terminal and not the third terminal, and connect the fourth terminal to the third terminal and not the second terminal.
<14>

A radio frequency circuit including:
a first filter adjustable to a first passband that includes an uplink band of a first band and an uplink band of a second band, and a second passband that includes the uplink band of the first band and is narrower than the first passband;
a second filter having a passband that includes a downlink band of the first band;
a third filter having a passband that includes a downlink band of the second band;
a fourth filter having a passband that includes a downlink band of a third band; and
a switch that includes a first terminal connected to an antenna connection terminal, a second terminal connected to the first filter and the second filter, a third terminal connected to the third filter, and a fourth terminal connected to the fourth filter, wherein
a combination of the first band and the second band is a band combination for simultaneous communication,
the uplink band of the first band is higher than the downlink band of the first band,
the uplink band of the second band is higher than the uplink band of the first band,
the downlink band of the second band is higher than the uplink band of the second band,
the downlink band of the third band is higher than the uplink band of the second band and lower than the downlink band of the second band, and
the first filter has a steeper attenuation slope on a higher frequency side of the first passband than on a lower frequency side of the first passband.
<15>

The radio frequency circuit according to <14>, wherein
in a first communication mode that simultaneously transfers (i) at least one of: a signal of the uplink band of the first band; a signal of the downlink band of the first band; or a signal of the uplink band of the second band and (ii) a signal of the downlink band of the second band:
   the switch is configured to connect the first terminal to the second terminal and the third terminal and not the fourth terminal; and
   the first filter is adjusted to the first passband, and
in a second communication mode that simultaneously transfers (i) at least one of a signal of the uplink band of the first band or a signal of the downlink band of the first band and (ii) a signal of the downlink band of the third band:
   the switch is configured to connect the first terminal to the second terminal and the fourth terminal and not the third terminal; and
   the first filter is adjusted to the second passband.
<16>

The radio frequency circuit according to <14> or <15>, wherein
the first band is Band 71 for LTE or n71 for 5G NR,
the second band is Band 85 for LTE or n85 for 5G NR, and
the third band is Band 29 for LTE or n29 for 5G NR.
<17>

The radio frequency circuit according to <14> or <15>, wherein
the first band is Band 105 for LTE or n105 for 5G NR,
the second band is Band 28 for LTE or n28 for 5G NR, and
the third band is Band 13 for LTE or n13 for 5G NR.
<18>

A radio frequency circuit including:
a first filter adjustable to a first passband that includes an uplink band of a first band and an uplink band of a second band, and a second passband that includes the uplink band of the first band and is narrower than the first passband;
a second filter having a passband that includes a downlink band of the first band;
a third filter adjustable to a third passband that includes a downlink band of the second band and a downlink band of a third band, and a fourth passband that includes the downlink band of the second band and is narrower than the third passband, wherein
a combination of the first band and the second band is a band combination for simultaneous communication,
the uplink band of the first band is higher than the downlink band of the first band,
the uplink band of the second band is higher than the uplink band of the first band,
the downlink band of the second band is higher than the uplink band of the second band,
the downlink band of the third band is higher than the uplink band of the second band and lower than the downlink band of the second band, and
the first filter has a steeper attenuation slope on a higher frequency side of the first passband than on a lower frequency side of the first passband.
<19>

The radio frequency circuit according to <18>, wherein
in a first communication mode that simultaneously transfers at least two of: a signal of the uplink band of the first band; a signal of the downlink band of the first band; a signal of the uplink band of the second band; or a signal of the downlink band of the second band:
   the first filter is adjusted to the first passband; and
   the third filter is adjusted to the fourth passband, and
in a second communication mode that simultaneously transfers (i) at least one of a signal of the uplink band of the first band or a signal of the downlink band of the first band and (ii) a signal of the downlink band of the third band:
   the first filter is adjusted to the second passband; and
   the third filter is adjusted to the third passband.
<20>

The radio frequency circuit according to <18> or <19>, wherein
the first band is Band 71 for LTE or n71 for 5G NR,
the second band is Band 85 for LTE or n85 for 5G NR, and
the third band is Band 29 for LTE or n29 for 5G NR.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to communication devices such as mobile phones as a radio frequency circuit disposed in the front-end portion.

1. A radio frequency circuit comprising:
a first filter having a passband that includes an uplink band of a first band and an uplink band of a second band;
a second filter having a passband that includes a downlink band of the first band;
a third filter having a passband that includes a downlink band of the second band;
a fourth filter having a passband that includes a downlink band of a third band; and
a switch that includes a first terminal connected to a first antenna connection terminal, a second terminal connected to the first filter, the second filter, and the third filter, and a third terminal connected to the fourth filter, wherein
a combination of the first band and the second band is a band combination for simultaneous communication,
the uplink band of the first band is higher than the downlink band of the first band,
the uplink band of the second band is higher than the uplink band of the first band,
the downlink band of the second band is higher than the uplink band of the second band,
the downlink band of the third band is higher than the uplink band of the second band and lower than the downlink band of the second band, and
the first filter has a steeper attenuation slope on a higher frequency side of the passband than on a lower frequency side of the passband.

2. The radio frequency circuit according to claim 1, wherein
the switch is configured to connect the first terminal exclusively to the second terminal, or to connect the first terminal exclusively to the third terminal.

3. The radio frequency circuit according to claim 2, wherein
in a first communication mode that simultaneously transfers at least two of: a signal of the uplink band of the first band; a signal of the downlink band of the first band; a signal of the uplink band of the second band; or a signal of the downlink band of the second band, the switch is configured to connect the first terminal to the second terminal and not the third terminal, and
in a second communication mode that transfers a signal of the downlink band of the third band, the switch is configured to connect the first terminal to the third terminal and not the second terminal.

4. The radio frequency circuit according to claim 1, wherein
the first filter is an acoustic wave filter that includes at least one series arm resonator and at least one parallel arm resonator,
the at least one series arm resonator includes a surface acoustic wave (SAW) resonator, and
the at least one parallel arm resonator includes a bulk acoustic wave (BAW) resonator.

5. The radio frequency circuit according to claim 1, wherein
the first filter includes:
a first piezoelectric layer on which an interdigital transducer (IDT) electrode is provided; and
a first high acoustic velocity layer disposed below the first piezoelectric layer, wherein a velocity of a bulk wave propagating in the first high acoustic velocity layer is higher than a velocity of an acoustic wave propagating in the first piezoelectric layer.

6. The radio frequency circuit according to claim 1, wherein
the first band is Band 71 for LTE or n71 for 5G NR,
the second band is Band 85 for LTE or n85 for 5G NR, and
the third band is Band 29 for LTE or n29 for 5G NR.

7. The radio frequency circuit according to claim 6, wherein
the passband of the first filter further includes an uplink band of at least one of: Band 12 for LTE; Band 105 for LTE; n12 for 5G NR; or n105 for 5G NR.

8. The radio frequency circuit according to claim 6, wherein
the passband of the second filter further includes a downlink band of at least one of Band 105 for LTE or n105 for 5G NR.

9. The radio frequency circuit according to claim 6, wherein
the passband of the third filter further includes a downlink band of at least one of: Band 12 for LTE; Band 13 for LTE; Band 14 for LTE; Band 67 for LTE; n12 for 5G NR; n13 for 5G NR; n14 for 5G NR; or n67 for 5G NR.

10. The radio frequency circuit according to claim 6, wherein
the passband of the fourth filter further includes an uplink band of at least one of Band 28 for LTE or n28 for 5G NR.

11. The radio frequency circuit according to claim 1, wherein
the first band is Band 105 for LTE or n105 for 5G NR,
the second band is Band 28 for LTE or n28 for 5G NR, and
the third band is Band 13 for LTE or n13 for 5G NR.

12. The radio frequency circuit according to claim 1, wherein
a combination of the first band and the third band is a band combination for simultaneous communication, and
the switch further includes a fourth terminal connected to a second antenna connection terminal.

13. The radio frequency circuit according to claim 12, wherein
in a third communication mode that simultaneously transfers (i) at least one of a signal of the uplink band of the first band or a signal of the downlink band of the first band and (ii) a signal of the downlink band of the third band, the switch is configured to connect the first terminal to the second terminal and not the third terminal, and connect the fourth terminal to the third terminal and not the second terminal.

14. A radio frequency circuit comprising:
a first filter adjustable to a first passband that includes an uplink band of a first band and an uplink band of a second band, and a second passband that includes the uplink band of the first band and is narrower than the first passband;
a second filter having a passband that includes a downlink band of the first band;
a third filter having a passband that includes a downlink band of the second band;
a fourth filter having a passband that includes a downlink band of a third band; and
a switch that includes a first terminal connected to an antenna connection terminal, a second terminal connected to the first filter and the second filter, a third terminal connected to the third filter, and a fourth terminal connected to the fourth filter, wherein
a combination of the first band and the second band is a band combination for simultaneous communication,
the uplink band of the first band is higher than the downlink band of the first band,
the uplink band of the second band is higher than the uplink band of the first band,
the downlink band of the second band is higher than the uplink band of the second band,
the downlink band of the third band is higher than the uplink band of the second band and lower than the downlink band of the second band, and
the first filter has a steeper attenuation slope on a higher frequency side of the first passband than on a lower frequency side of the first passband.

15. The radio frequency circuit according to claim 14, wherein
in a first communication mode that simultaneously transfers (i) at least one of: a signal of the uplink band of the first band; a signal of the downlink band of the first band; or a signal of the uplink band of the second band and (ii) a signal of the downlink band of the second band:
the switch is configured to connect the first terminal to the second terminal and the third terminal and not the fourth terminal; and
the first filter is adjusted to the first passband, and
in a second communication mode that simultaneously transfers (i) at least one of a signal of the uplink band of the first band or a signal of the downlink band of the first band and (ii) a signal of the downlink band of the third band:
the switch is configured to connect the first terminal to the second terminal and the fourth terminal and not the third terminal; and
the first filter is adjusted to the second passband.

16. The radio frequency circuit according to claim 14, wherein
the first band is Band 71 for LTE or n71 for 5G NR,
the second band is Band 85 for LTE or n85 for 5G NR, and
the third band is Band 29 for LTE or n29 for 5G NR.

17. The radio frequency circuit according to claim 14, wherein
the first band is Band 105 for LTE or n105 for 5G NR,
the second band is Band 28 for LTE or n28 for 5G NR, and
the third band is Band 13 for LTE or n13 for 5G NR.

18. A radio frequency circuit comprising:
a first filter adjustable to a first passband that includes an uplink band of a first band and an uplink band of a second band, and a second passband that includes the uplink band of the first band and is narrower than the first passband;
a second filter having a passband that includes a downlink band of the first band;
a third filter adjustable to a third passband that includes a downlink band of the second band and a downlink band of a third band, and a fourth passband that includes the downlink band of the second band and is narrower than the third passband, wherein
the first filter, the second filter, and the third filter are connected to a common antenna connection terminal,
a combination of the first band and the second band is a band combination for simultaneous communication,
the uplink band of the first band is higher than the downlink band of the first band,
the uplink band of the second band is higher than the uplink band of the first band,
the downlink band of the second band is higher than the uplink band of the second band,
the downlink band of the third band is higher than the uplink band of the second band and lower than the downlink band of the second band, and
the first filter has a steeper attenuation slope on a higher frequency side of the first passband than on a lower frequency side of the first passband.

19. The radio frequency circuit according to claim 18, wherein
in a first communication mode that simultaneously transfers at least two of: a signal of the uplink band of the first band; a signal of the downlink band of the first band; a signal of the uplink band of the second band; or a signal of the downlink band of the second band:
the first filter is adjusted to the first passband; and
the third filter is adjusted to the fourth passband, and
in a second communication mode that simultaneously transfers (i) at least one of a signal of the uplink band of the first band or a signal of the downlink band of the first band and (ii) a signal of the downlink band of the third band:
the first filter is adjusted to the second passband; and
the third filter is adjusted to the third passband.

20. The radio frequency circuit according to claim 18, wherein
the first band is Band 71 for LTE or n71 for 5G NR,
the second band is Band 85 for LTE or n85 for 5G NR, and
the third band is Band 29 for LTE or n29 for 5G NR.
